(19) United States
(12) Patent Application Publication
(10) Pub. No.: US 2020/0185527 A1
(43) Pub. Date: Jun. 11, 2020

(54) THIN-FILM TRANSISTOR AND METHOD OF PRODUCING THIN-FILM TRANSISTOR

(71) Applicant: Sharp Kabushiki Kaisha, Sakai City, Osaka (JP)

(72) Inventor: Tadayoshi MIYAMOTO, Sakai City (JP)

(21) Appl. No.: 16/095,390

(22) PCT Filed: Apr. 20, 2017
(86) PCT No.: PCT/JP2017/015826

§ 371 Date: Oct. 22, 2018

(30) Foreign Application Priority Data
Apr. 27, 2016 (JP) 2016-089364

(51) Int. Cl. H01L 29/786; H01L 29/423; H01L 29/66

(52) U.S. Cl. CPC H01L 29/7869; H01L 29/78645; H01L 29/78696; H01L 29/66969; H01L 29/42384

(57) ABSTRACT

A gate driver TFT 30 includes a first gate electrode 30a formed from a first metal film 15, a second gate electrode 31 formed from a second metal film 19 and overlapping a part of the first gate electrode 30a, an electrode 32 formed from the second metal film 19 overlapping a part of the first gate electrode 30a and disposed away from the second gate electrode 31 at an interval, channel portions 30d formed from the oxide semiconductor film 17 and one of which overlaps the second gate electrode 31 and another one of which overlaps the electrode 32, and a first low-resistance portion 33 formed from the oxide semiconductor film 17, the first-low resistance portion not overlapping the second gate electrode 31 and the electrode 32 and disposed between at least the channel portions 30d and having a resistance lower than that of the channel portions 30d.

### TECHNICAL FIELD

The present invention relates to a thin-film transistor and a method of producing a thin-film transistor.

### BACKGROUND ART

Conventionally, a thin-film transistor that is used as a switching element in a display panel, such as a liquid crystal panel, is known, as disclosed in Patent Document 1. The thin-film transistor has a multigate structure including an oxide semiconductor film formed on an insulating surface, a first gate insulating film in contact with a first surface of the oxide semiconductor film, a first gate electrode disposed on the insulating surface and the oxide semiconductor film, a second first gate insulating film in contact with a second surface of the oxide semiconductor film, and a second gate electrode in contact with the second first gate insulating film. The oxide semiconductor film includes a first region that overlaps the first gate electrode, and a second region that does not overlap the first gate electrode. The second gate electrode overlaps the first region and the second region of the oxide semiconductor film.

### RELATED ART DOCUMENT

### Patent Document

Patent Document 1: Japanese Unexamined Patent Application Publication No. 2015-46580

### Problem to be Solved by the Invention

Patent Document 1 indicates that the thin-film transistor makes it possible to achieve a further decrease in current that flows between the source electrode and the drain electrode when the gate electrode voltage is 0 V. However, in the thin-film transistor disclosed in Patent Document 1, the electrically conductive film configuring an intermediate electrode interposed between the source electrode and the drain electrode, and the electrically conductive film configuring the second gate electrode are in different layers. Accordingly, parasitic capacitance due to an overlap between the intermediate electrode and the second gate electrode is liable to be caused. In addition, variations are liable to be caused in the amount of overlap and the magnitude of the parasitic capacitance.

### DISCLOSURE OF THE PRESENT INVENTION

The present invention has been made in view of the above circumstances. An object of the present invention is to reduce parasitic capacitance stably.

### Means for Solving the Problem

A thin-film transistor according to the present invention includes a first electrically conductive film, a semiconductor film disposed on an upper layer-side with respect to the first electrically conductive film while having a first insulating film therebetween, a second electrically conductive film disposed on an upper layer-side with respect to the semiconductor film while having a second insulating film therebetween, a first gate electrode formed from the first electrically conductive film, a second gate electrode formed from the second electrically conductive film and overlapping a part of the first gate electrode, an electrode formed from the second electrically conductive film, overlapping a part of the first gate electrode, and disposed away from the second gate electrode at an interval, channel portions formed from the semiconductor film, one of the channel portions overlapping the second gate electrode and another one of the channel portions overlapping the electrode, and a low-resistance portion formed from the semiconductor film, the low-resistance portion not overlapping the second gate electrode and the electrode, disposed between at least the channel portions, and having a resistance lower than that of the channel portion.

In this way, as a signal is supplied to the first gate electrode overlapping the plurality of channel portions, charge moves from the channel portion on the charge-supplying side to the low-resistance portion, and from the low-resistance portion to the channel portion on the charge-supplied side. Thus, the charge moves through the plurality of channel portions via the low-resistance portion having a resistance lower than that of the channel portions. Accordingly, it becomes possible to preferably mitigate the electric field concentration caused at the interface between the semiconductor film and the first insulating film on the charge-supplied side. As a result, it becomes possible to increase the breakdown voltage of the thin-film transistor. In addition, as a signal is supplied to the second gate electrode, the amount of charge circulated through the channel portion overlapping the second gate electrode is increased. In this way, the decrease in current caused by an increase in the length of the charge circulation route due to the plurality of channel portions can be suppressed.

The second gate electrode and the electrode are both made of the second electrically conductive film and disposed to overlap the plurality of channel portions. Accordingly, even if charge is generated on the upper layer-side of the second electrically conductive film, an electric field due to the charge is blocked by the second gate electrode and the electrode. As a result, the formation of a back channel in the channel portions due to the electric field becomes difficult. Thus, sufficiently high operation reliability of the thin-film transistor can be maintained.

The low-resistance portion is made of the portion of the semiconductor film that does not overlap the second gate electrode and the electrode and that is disposed between at least a plurality of channel portions. Accordingly, it is possible to provide the low-resistance portion by partially reducing the resistance of the semiconductor film by utilizing the arrangement of the second gate electrode and the electrode during manufacture. In this way, it becomes possible to obtain the non-overlapping arrangement between the second gate electrode and the electrode and the low-resistance portion in a self-aligning manner, whereby the parasitic capacitance that could be introduced therebetween can be stably reduced.

Embodiments of the present invention may include the following preferable configurations.

(1) The semiconductor film may include second low-resistance portions each of which is continuous to another end of each of the channel portions of which one end thereof is continuous to the low-resistance portion, the second low-resistance portions do not overlap the second gate electrode and the electrode and have a resistance lower than that of the channel portions. In this way, it is possible to provide a pair of second low-resistance portions, in addition to the low-resistance portion, by partially reducing the resistance of the semiconductor film by utilizing the arrangement of the second gate electrode and the electrode during manufacture. In this way, it becomes possible to obtain the non-overlapping arrangement between the second gate electrode and the electrode and the low-resistance portion and the pair of second low-resistance portions in a self-aligning manner. As a result, the parasitic capacitance that could be introduced between the second gate electrode and the electrode and the low-resistance portion and the pair of second low-resistance portions can be stably reduced.

(2) The semiconductor film may be formed of an oxide semiconductor film. In this way, compared with amorphous silicon, generally a greater bandgap is obtained. Accordingly, when the semiconductor film is an oxide semiconductor film, it becomes possible to further increase the breakdown voltage of the thin-film transistor.

(3) The thin-film transistor may further include a third insulating film disposed on the upper layer-side of the second electrically conductive film and made of a material containing hydrogen. In this way, the hydrogen contained in the material of the third insulating film is diffused into the portions of the oxide semiconductor film that do not overlap the second gate electrode and the electrode, whereby the portions are reduced in resistance.

(4) The second gate electrode may be connected to the first gate electrode via a contact hole formed in the first insulating film and the second insulating film. In this way, the signal supplied to the first gate electrode is also supplied to the second gate electrode via the contact hole, making it possible to easily synchronize the first gate electrode and the second gate electrode.

(5) The electrode may be connected to the second gate electrode. In this way, the electrode is supplied with a signal synchronized with the first gate electrode and the second gate electrode. Accordingly, the amount of charge circulated is also increased in the channel portion overlapping the electrode, in addition to in the channel portion overlapping the second gate electrode.

(6) The thin-film transistor may further include a source electrode connected to another end of the channel portions of which one end is continuous to the low-resistance portion, and the electrode may be connected to the source electrode. In this way, the electrode is supplied with a signal synchronized with the source electrode. Accordingly, it is possible to further preferably mitigate the electric field concentration at the interface between the semiconductor film and the first insulating film.

(7) The thin-film transistor may further include a source electrode connected to another end side of the channel portion of which one end side is continuous to the low-resistance portion, and the electrode may be supplied with a signal of a voltage lower than a voltage applied to the source electrode. In this way, as the electrode is supplied with the signal of a voltage lower than a voltage applied to the source electrode, a threshold voltage relating to the thin-film transistor is increased. In this way, it becomes possible to reduce the current that can flow through each of the channel portions in a state in which no signal is being supplied to the first gate electrode and the second gate electrode.

A method of producing a thin-film transistor according to the present invention includes a first gate electrode forming step of forming a first gate electrode by forming a first electrically conductive film and patterning the first electrically conductive film, a first insulating film forming step of forming a first insulating film on an upper layer-side of the first electrically conductive film, an oxide semiconductor film forming step of forming an oxide semiconductor film on an upper layer-side of the first insulating film and patterning the oxide semiconductor film, a second insulating film forming step of forming a second insulating film on an upper layer-side of the oxide semiconductor film, a second gate electrode and electrode forming step of forming a second electrically conductive film on an upper layer-side of the second insulating film, patterning the second electrically conductive film to form a second gate electrode overlapping a part of the first gate electrode and form an electrode overlapping a part of the first gate electrode and disposed away from the second gate electrode at an interval, and removing portions of the second insulating film that do not overlap the second gate electrode and the electrode, and a third insulating film forming step/low-resistance portion forming step of forming a third insulating film made of a material containing hydrogen on an upper layer-side of the second electrically conductive film and according to the forming of the third insulating film, forming a low-resistance portion included in portions of the oxide semiconductor film that do not overlap the second gate electrode and the electrode and having a resistance lower than that of channel portions that are formed from the oxide semiconductor film and one of which overlaps the second gate electrode and another one of which overlaps the electrode.

After the first gate electrode forming step, the first insulating film forming step, the oxide semiconductor film forming step, and the second insulating film forming step, the second gate electrode and the electrode forming step is performed, forming the second gate electrode formed from the second electrically conductive film and overlapping a part of the first gate electrode, and the electrode formed from the second electrically conductive film, overlapping a part of the first gate electrode, and disposed away from the second gate electrode. In this case, the portions of the second insulating film that do not overlap the second gate electrode and the electrode are removed. In the subsequent third insulating film forming step/low-resistance portion forming step, the third insulating film made of material containing hydrogen is formed on the upper layer-side of the second electrically conductive film. In this case, in the portions of the oxide semiconductor film that do not overlap the second gate electrode and the electrode, the hydrogen contained in the material of the third insulating film is diffused. As a result, the resistance of the portions is reduced, forming the low-resistance portion in which the resistance is lower than that of the channel portions formed from the oxide semiconductor film that overlap the second gate electrode and the electrode.

Thus, the low-resistance portion can be provided by partially reducing the resistance of the oxide semiconductor film by utilizing the arrangement of the second gate electrode and the electrode. Accordingly, it becomes possible to obtain the non-overlapping arrangement between the second gate electrode and the electrode and the low-resistance portion in a self-aligning manner, whereby the parasitic capacitance that could be introduced therebetween can be stably reduced.

### Advantageous Effect of the Invention

According to the present invention, parasitic capacitance can be stably reduced.

### BRIEF DESCRIPTION OF THE DRAWINGS

FIG. 1 is a schematic cross sectional view illustrating a cross section configuration of a liquid crystal panel according to the first embodiment of the present invention.

FIG. 2 is a plan view showing a wire configuration of pixel TFTs provided in the liquid crystal panel.

FIG. 3 is a cross sectional view of an intersecting portion of a gate wire and a source wire provided in the liquid crystal panel.

FIG. 4 is a cross sectional view of a pixel TFT provided in the liquid crystal panel.

FIG. 5 is a plan view of a gate driver TFT provided in the liquid crystal panel.

FIG. 6 is a cross sectional view taken along line A-A of FIG. 5.

FIG. 7 is a cross sectional view taken along line B-B of FIG. 5.

FIG. 8 is a cross sectional view taken along line A-A of FIG. 5 in a state in which a second gate insulating film forming step included in a gate driver TFT manufacturing method has been performed.

FIG. 9 is a cross sectional view taken along line B-B of FIG. 5 in the state in which the second gate insulating film forming step included in the gate driver TFT manufacturing method has been performed.

FIG. 10 is a cross sectional view taken along line A-A of FIG. 5 in a state in which a second gate electrode and electrode forming step included in the gate driver TFT manufacturing method is being performed.

FIG. 11 is a cross sectional view taken along line B-B of FIG. 5 in a state in which the second gate electrode and the electrode forming step included in the gate driver TFT manufacturing method is being performed.

FIG. 12 is a cross sectional view taken along line A-A of FIG. 5 in a state in which an interlayer insulating film forming step/low-resistance portion forming step included in the gate driver TFT manufacturing method is being performed.

FIG. 13 is a cross sectional view taken along line B-B of FIG. 5 in a state in which the interlayer insulating film forming step/low-resistance portion forming step included in the gate driver TFT manufacturing method is being performed.

FIG. 14 is a cross sectional view taken along line A-A of FIG. 5 in a state in which a source electrode and drain electrode forming step included in the gate driver TFT manufacturing method has been performed.

FIG. 15 is a plan view of a gate driver TFT according to the second embodiment of the present invention.

FIG. 16 is a cross sectional view taken along line B-B of FIG. 15.

FIG. 17 is a cross sectional view taken along line C-C of FIG. 15.

FIG. 18 is a plan view of a gate driver TFT according to the third embodiment of the present invention.

### MODES FOR CARRYING OUT THE INVENTION

### First Embodiment

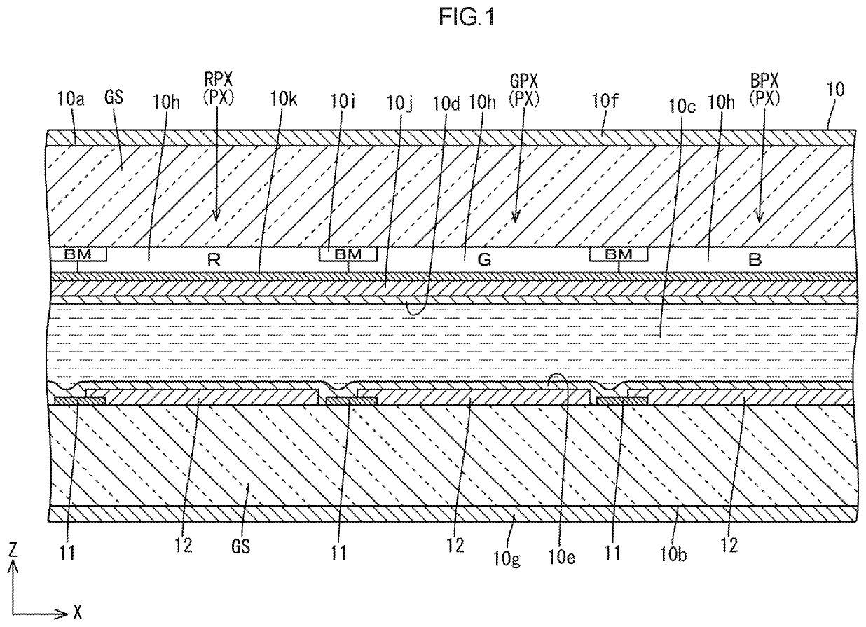

The first embodiment of the present invention will be described with reference to FIG. 1 to FIG. 14. In the present embodiment, a gate driver TFT (thin-film transistor) 30 provided in a liquid crystal panel (display panel) 10 will be described by way of example. In a part of each of the drawing figures, an X-axis, a Y-axis, and a Z-axis are indicated, the axis directions corresponding to the directions indicated in the drawing figures.

The configuration of the liquid crystal panel 10 will be described. As illustrated in FIG. 1, the liquid crystal panel 10 includes a pair of transparent (highly optically transmissive) substrates 10a, 10b and a liquid crystal layer 10c that is interposed between the substrates 10a, 10b and includes liquid crystal molecules made of a substance of which optical characteristics can be varied by application of an electric field. The substrates 10a, 10b are bonded to each other by means of a sealing agent (not illustrated), with a cell gap corresponding to the thickness of the liquid crystal layer 10c maintained therebetween. Each of the substrates 10a, 10b includes a substantially transparent glass substrate GS. On each glass substrate GS, a plurality of films are stacked by a known photolithography method, for example. Of the substrates 10a, 10b, the upper side (front side) is a CF substrate (counter substrate) 10a, and the back side (rear side) is an array substrate (thin-film transistor substrate; active matrix substrate) 10b. Polarizing plates 10f, 10g are affixed to the outer surface of the substrates 10a, 10b, respectively. On the inner surface side of the substrates 10a, 10b, there are formed alignment films 10d, 10e respectively for aligning the liquid crystal molecules included in the liquid crystal layer 10c.

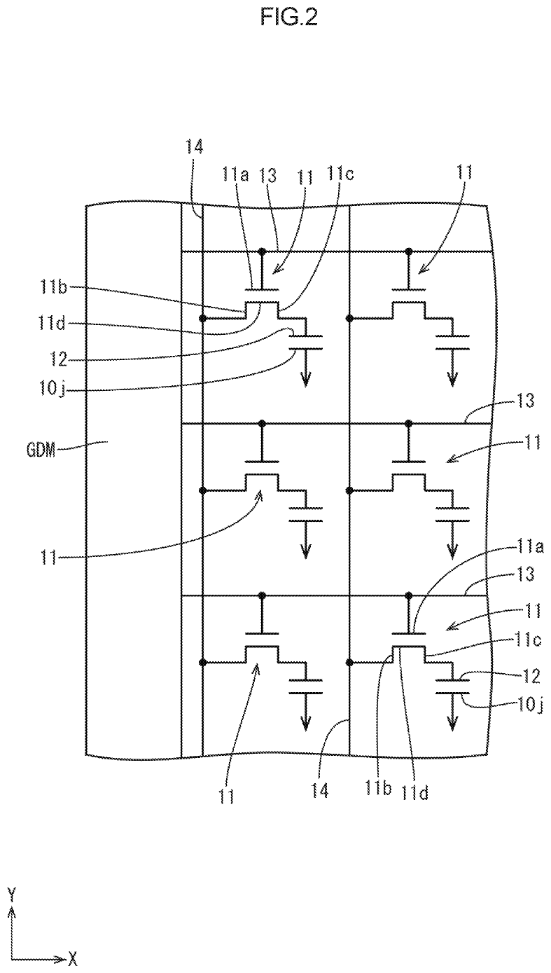

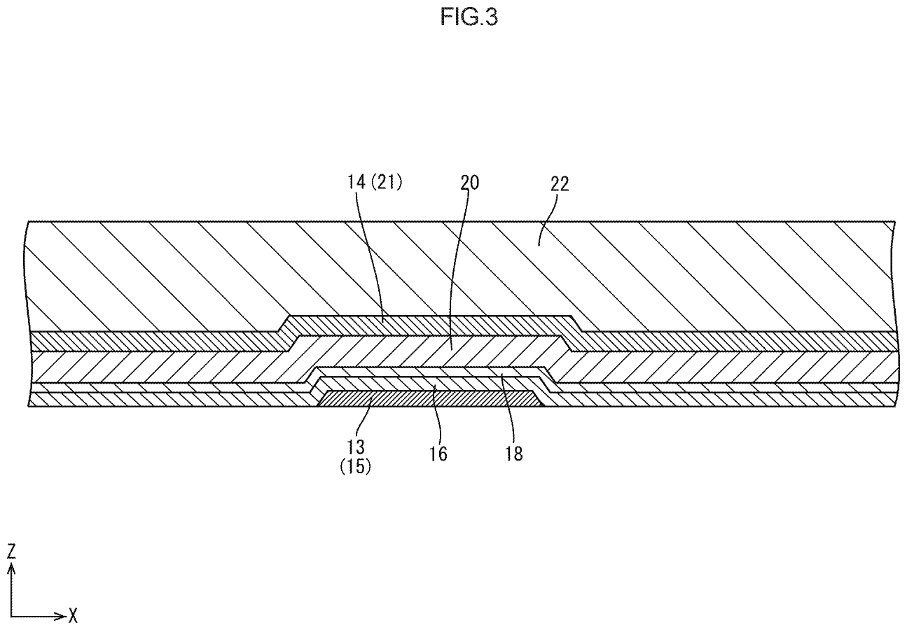

On the inner surface side of the array substrate 10b, in a display area in the center of the screen in which an image is displayed, as illustrated in FIG. 2, a number of pixel TFTs (thin-film transistors) 11 which are switching elements and a number of pixel electrodes 12 are arranged in a matrix. The pixel TFTs 11 and the pixel electrodes 12 are surrounded by a number of gate wires 13 and a number of source wires 14 forming a lattice. In other words, the pixel TFTs 11 and the pixel electrodes 12 are arranged side by side in rows and columns in the vicinity of the intersecting portions of the gate wires 13 and the source wires forming a lattice. As illustrated in FIG. 3, in the intersecting portion between the gate wire 13 and the source wire 14, a plurality of insulating films 16, 18, 20 are interposed to maintain an insulated state between the wires 13, 14.

Specifically, in the intersecting portion between the gate wire 13 and the source wire 14, which are respectively made of a first metal film 15 and a third metal film 21 as will be described later, three layers of a first gate insulating film 16, a second gate insulating film 18, and an interlayer insulating film 20 are interposed. Accordingly, not only the wires 13, 14 are maintained in an insulated state, but also, compared with a configuration in which two layers of insulating films were to be interposed, cross capacitance (parasitic capacitance) introduced in the intersecting portion between the wires 13, 14 is reduced. The pixel electrodes 12 have a longitudinal quadrangular (rectangular) shape occupying the region surrounded by the gate wires 13 and the source wires 14, as viewed in plan. It is also possible to provide the array substrate 10b with an auxiliary capacitance wire (not illustrated) that extends along the gate wires 13 and across the pixel electrodes 12.

As illustrated in FIG. 2, in a frame-shaped non-display region surrounding the display region on the inner surface side of the array substrate 10b, a gate driver circuit portion GDM is provided which is connected to the ends of a number of the gate wires 13 and supplies scan signals to the gate wires 13. The gate driver circuit portion GDM includes a number of gate driver TFTs (thin-film transistors) 30, for example, in which an oxide semiconductor film 17 is used, as in the pixel TFTs 11 of which pixels PX are configured in the display area. The gate driver circuit portion GDM is formed on the array substrate 10b in a monolithic manner, using the oxide semiconductor film 17 as a base. The gate driver circuit portion GDM includes a buffer circuit for amplifying the scan signals. Gate driver TFTs 30 of which the buffer circuit is configured tend to have a higher applied drain voltage compared with the pixel TFTs 11 of which the pixels PX are configured in the display area. The gate driver circuit portion GDM extends in the Y-axis direction, i.e., the direction in which the gate wires 13 are arranged.

As illustrated in FIG. 1, in the display area on the inner surface side of the CF substrate 10a, there is provided a color filter 10h made of three colored portions of red (R), green (G), and blue (B). A plurality of each of the colored portions configuring the color filter 10h are arranged in rows and columns (in a matrix) in the row direction (X-axis direction) and the column direction (Y-axis direction) so as to overlap the respective pixel electrodes 12 on the array substrate 10b side, as viewed in plan. Between the colored portions configuring the color filter 10h, substantially lattice-shaped light-blocking portions (black matrix, light-blocking area) 10i are formed to prevent mixing of colors. The light-blocking portions 10i are disposed so as to overlap the gate wires 13 and the source wires 14, as viewed in plan. The colored portions configuring the color filter 10h have a film thickness greater than that of the light-blocking portions 10i, and are disposed so as to cover the light-blocking portions 10i. In the liquid crystal panel 10, individual pixels PX that are display units are configured of sets of the three colored portions R, G, and B of the color filter 10h, the three pixel electrodes 12 opposing the respective colored portions, and the three pixel TFTs 11 respectively connected to the pixel electrodes 12. The pixels PX include a red pixel RPX having a red colored portion, a green pixel GPX having a green colored portion, and a blue pixel BPX having a blue colored portion. The pixels RPX, GPX, and BPX of the respective colors are disposed on a plate surface of the liquid crystal panel 10 in a repetitive manner in the row direction (X-axis direction), thus configuring a pixel group. A number of the pixel groups are arranged side by side in the column direction (Y-axis direction).

As illustrated in FIG. 1, on a surface of the color filter 10h and the light-blocking portions 10i, an overcoat film 10k is disposed overlapping on the inner side. The overcoat film 10k is formed substantially throughout the inner surface of the CF substrate 10a as a solid film, and has a film thickness greater than or equal to that of the color filter 10h. On a surface of the overcoat film 10k, a counter electrode 10j is disposed overlapping on the inner side. The counter electrode 10j is formed substantially throughout the inner surface of the CF substrate 10a as a solid film. The counter electrode 10j is made of a transparent electrode material, such as an indium tin oxide (ITO). The counter electrode 10j is maintained at a certain reference potential at all times. Accordingly, when the pixel TFTs 11 are driven and potentials are supplied to the pixel electrodes 12 connected to the pixel TFTs 11, potential differences are caused between the counter electrode 10j and the pixel electrodes 12. Based on the potential differences caused between the counter electrode 10j and the pixel electrodes 12, the alignment state of the liquid crystal molecules included in the liquid crystal layer 10c is changed. As a result, the polarization state of the transmitted light is changed, whereby the amount of light transmitted through the liquid crystal panel 10 is separately controlled on a pixel PX by pixel PX basis and a predetermined color image is displayed.

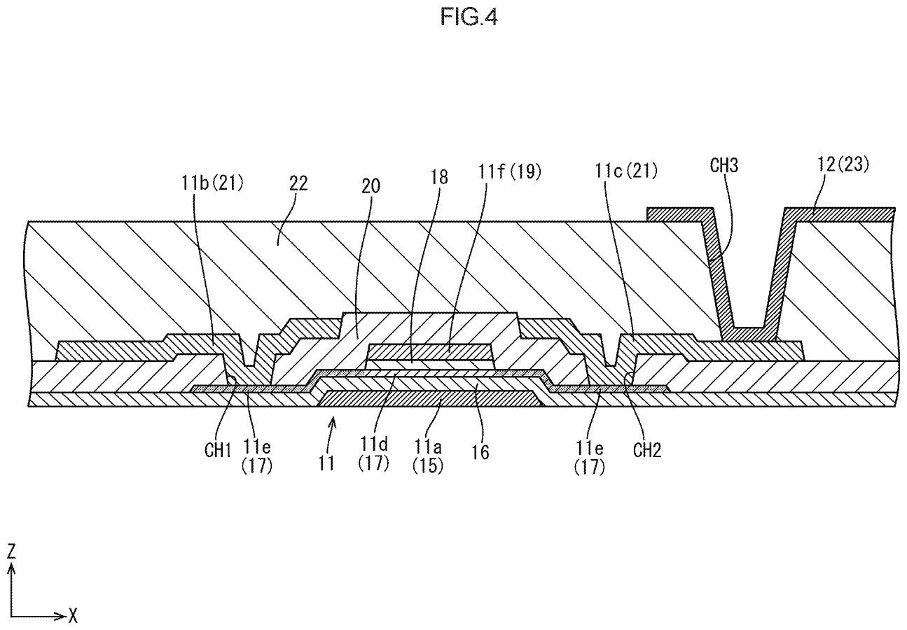

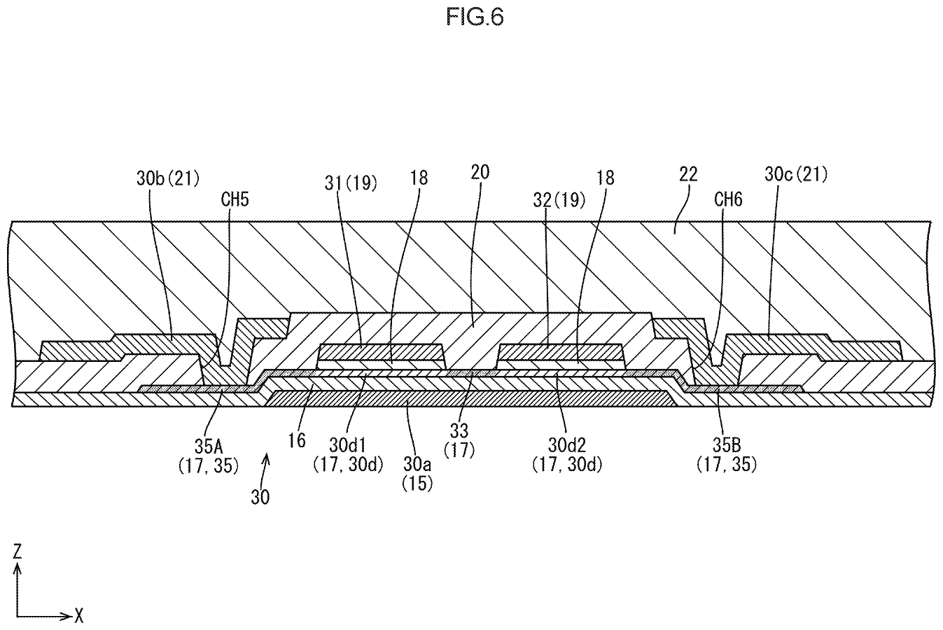

The various films stacked and formed on the inner surface side of the array substrate 10b will be described. As illustrated in FIG. 4 and FIG. 6, on the array substrate 10b, there are stacked and formed, in order from the lower layer (glass substrate GS) side: a first metal film (first electrically conductive film) 15; a first gate insulating film (first insulating film; lower layer-side gate insulating film) 16; an oxide semiconductor film (semiconductor film) 17; a second gate insulating film (second insulating film; upper layer-side gate insulating film) 18; a second metal film (second electrically conductive film) 19; an interlayer insulating film (third insulating film) 20; a third metal film (third electrically conductive film) 21; a planarization film (fourth insulating film) 22; and a transparent electrode film (fourth electrically conductive film) 23. In FIG. 4 and FIG. 6, illustration of the alignment film 10e stacked on the upper layer-side of the transparent electrode film 23 is omitted.

The first metal film 15 is an electrically conductive film made of a metal material (such as Mo, Ti, Al, Cr, or Au), and preferably has a film thickness in a range of from 50 nm to 300 nm, for example. Preferably, the first metal film 15 is patterned by, for example, a photolithography method and dry etching after a film is formed by sputtering. The first metal film 15 mainly configures the gate wires 13 and first gate electrodes 11a, 30a respectively of the TFTs 11, 30, which will be described later. As illustrated in FIG. 4 and FIG. 6, the first gate insulating film 16 is stacked on the upper layer-side of the first metal film 15. The first gate insulating film 16 is configured of, e.g., two layers of laminated films made of inorganic material, such as silicon oxide (SiO₂) or silicon nitride (SiNₓ). In FIG. 4 and FIG. 6, illustration of the layer structure of the first gate insulating film 16 is omitted. The first gate insulating film 16 is interposed between the first metal film 15 and the oxide semiconductor film 17, and provides insulation therebetween. Preferably, the first gate insulating film 16 has two layers that are successively formed by chemical vapor deposition (CVD). During film formation, a rare gas element, such as argon gas, may be included in the reaction gas. In this way, the forming temperature can be decreased and a dense film can be obtained, making it possible to reduce gate leak current.

As illustrated in FIG. 4 and FIG. 6, the oxide semiconductor film 17 is stacked on the upper layer-side of the first gate insulating film 16. The oxide semiconductor film 17 is made of a thin-film of an oxide semiconductor material. Preferably, the oxide semiconductor film 17 has a film thickness of about 30 nm to 100 nm, for example. The oxide semiconductor included in the oxide semiconductor film 17 may be an amorphous oxide semiconductor or a crystalline oxide semiconductor having a crystalline portion. Examples of crystalline oxide semiconductor include a polycrystalline oxide semiconductor, a microcrystalline oxide semiconductor, and a crystalline oxide semiconductor in which a c-axis is aligned generally perpendicularly to the layer surface. The oxide semiconductor film 17 may have a laminated structure of two or more layers. When the oxide semiconductor film 17 has a laminated structure, the oxide semiconductor film 17 may include an amorphous oxide semiconductor layer and a crystalline oxide semiconductor layer. Alternatively, the oxide semiconductor film 17 may include a plurality of crystalline oxide semiconductor layers having different crystal structures. The oxide semiconductor film 17 may include a plurality of amorphous oxide semiconductor layers. When the oxide semiconductor film 17 has a double-layer structure including an upper layer and a lower layer, the oxide semiconductor included in the upper layer preferably has an energy gap greater than an energy gap of the oxide semiconductor included in the lower layer. However, when the difference in energy gap between the layers is relatively small, the energy gap of the oxide semiconductor of the lower layer may be greater than the energy gap of the oxide semiconductor of the upper layer.

The materials and structures of amorphous oxide semiconductors and the crystalline oxide semiconductors, methods of forming the films thereof, configurations and the like of the oxide semiconductor film 17 having a laminated structure are described in Japanese Unexamined Patent Application Publication No. 2014-007399, for example. The contents of the disclosure of Japanese Unexamined Patent Application Publication No.

2014-007399 are incorporated herein by reference. The oxide semiconductor film 17 may include at least one metal element among In, Ga, and Zn. In the present embodiment, the oxide semiconductor film 17 includes an In—Ga—Zn—O-based semiconductor (such as an indium gallium zinc oxide), for example. Herein, the In—Ga—Zn—O-based semiconductor is a ternary oxide of In (indium), Ga (gallium), and Zn (zinc), where the ratio (composition ratio) of In, Ga, and Zn is not particularly limited and may include In:Ga:Zn=2:2:1, In:Ga:Zn=1:1:1, and In:Ga:Zn=1:1:2, for example. The oxide semiconductor film 17 may be formed of an oxide semiconductor film including an In—Ga—Zn—O-based semiconductor. The In—Ga—Zn—O-based semiconductor may be amorphous or crystalline. Preferably, the crystalline In—Ga—Zn—O-based semiconductor is made of a crystalline In—Ga—Zn—O-based semiconductor in which a c-axis is generally perpendicularly aligned to the layer surface.

The crystal structure of the crystalline In—Ga—Zn—O-based semiconductor is disclosed in, for example: Japanese Unexamined Patent Application Publication No. 2014-007399 mentioned above; Japanese Unexamined Patent Application Publication No. 2012-134475; and Japanese Unexamined Patent Application Publication No. 2014-209727. The contents of the disclosures of Japanese Unexamined Patent Application Publication No. 2012-134475 and Japanese Unexamined Application Patent Publication No. 2014-209727 are incorporated herein by reference. A TFT having an In—Ga—Zn—O-based semiconductor layer has a high mobility (higher than that of an a-Si TFT by a factor of more than 20) and a low leak current (less than one-hundredth that of an a-Si TFT). Accordingly, the TFT may be preferably used as the gate driver TFTs 30 (such as the TFT included in the gate driver circuit portion (drive circuit) GDM disposed on the same glass substrate GS as that of the display area, in the vicinity of the display area including a plurality of pixels PX) and the pixel TFTs 11 (the TFTs configuring the pixels PX).

The oxide semiconductor film 17 may include another oxide semiconductor, instead of the In—Ga—Zn—O-based semiconductor. For example, the oxide semiconductor film 17 may include an In—Sn—Zn—O-based semiconductor (such as In₂O₃—SnO₂—ZnO; InSnZnO). The In—Sn—Zn—O-based semiconductor is a ternary oxide of In (indium), Sn (tin), and Zn (zinc). Alternatively, the oxide semiconductor film 17 may include, for example: an In—Al—Zn—O-based semiconductor; an In—Al—Sn—Zn—O-based semiconductor; a Zn—O-based semiconductor; an In—Zn—O-based semiconductor; a Zn—Ti—O-based semiconductor; a Cd—Ge—O-based semiconductor; a Cd—Pb—O-based semiconductor; CdO (cadmium oxide); a Mg—Zn—O-based semiconductor; an In—Ga—Sn—O-based semiconductor; an In—Ga—O-based semiconductor; a Zr—In—Zn—O-based semiconductor; or a Hf—In—Zn—O-based semiconductor.

As illustrated in FIG. 4 and FIG. 6, the second gate insulating film 18 is stacked on the upper layer-side of the oxide semiconductor film 17. The second gate insulating film 18 is formed from a monolayer film made of an inorganic material, such as silicon oxide (SiO₂). The second gate insulating film 18 is interposed between the oxide semiconductor film 17 and the second metal film 19 and provides insulation therebetween. The second gate insulating film 18 has a film thickness smaller than a film thickness of the first gate insulating film 16. This makes it possible to increase the on-current of the pixel TFTs 11 and the gate driver TFTs 30, as will be described later. Preferably, the second gate insulating film 18 is formed by chemical vapor deposition (CVD), for example. The second metal film 19 is stacked on the upper layer-side of the second gate insulating film 18. The second metal film 19 is an electrically conductive film made of metal material (such as Mo, Ti, Al, Cr, or Au). Preferably, the second metal film 19 is patterned by photolithography and dry etching after film formation by sputtering, for example. The second metal film 19 mainly configures a second gate electrode 11f of the pixel TFTs 11, and a second gate electrode 31 and an electrode 32 of the gate driver TFTs 30, as will be described later.

As illustrated in FIG. 4 and FIG. 6, the interlayer insulating film 20 is stacked on the upper layer-side of at least the second metal film 19. The interlayer insulating film 20 is formed from two layers of laminated films made of inorganic material, such as silicon oxide (SiO₂) or silicon nitride (SiNₓ). More specifically, the interlayer insulating film 20 includes a layer made of silicon nitride at least on the lower layer side thereof (the side contacting the oxide semiconductor film 17). In FIG. 4 and FIG. 6, illustration of the layer structure of the interlayer insulating film 20 is omitted. Preferably, the interlayer insulating film 20 has two layers that are successively formed by chemical vapor deposition (CVD). The interlayer insulating film 20 is interposed between the oxide semiconductor film 17 and second metal film 19 and the third metal film 21, and provides insulation therebetween. The third metal film 21 is stacked on the upper layer-side of the interlayer insulating film 20. The third metal film 21 is an electrically conductive film made of metal material (such as Mo, Ti, Al, Cr, or Au). Preferably, the third metal film 21 is patterned by photolithography and dry etching following film formation by sputtering, for example. The third metal film 21 mainly configures the source wires 14, and source electrodes 11b, 30b and drain electrodes 11c, 30c of the TFTs 11, 30, as will be described later.

As illustrated in FIG. 4 and FIG. 6, the planarization film 22 is stacked on the upper layer-side of the third metal film 21. The planarization film 22 is made of synthetic resin material, such as acrylic resin (PMMA), and preferably has a film thickness on the order of 2 μm, for example. That is, the film thickness of the planarization film 22 is made greater than the film thickness of the other insulating films 16, 18, 20 so as to planarize the surface of the array substrate 10b. Preferably, the planarization film 22 is formed by slit coating or spin coating, for example. The planarization film 22 is interposed between the third metal film 21 and the transparent electrode film 23 to provide insulation therebetween. The transparent electrode film 23 is stacked on the upper layer-side of the planarization film 22. The transparent electrode film 23 is a type of electrically conductive film, is made of transparent electrode material such as indium zinc oxide (IZO), and has a film thickness on the order of 100 nm, for example. Preferably, the transparent electrode film 23 is formed by sputtering, for example. The transparent electrode film 23 mainly configures the pixel electrodes 12.

The configuration of the pixel TFTs 11 will be described. As illustrated in FIG. 4, the pixel TFT 11 includes at least the first gate electrode (lower layer-side gate electrode) 11a, a channel portion 11d, a source electrode 11b connected to one end side of the channel portion 11d, and a drain electrode 11c connected to another end side of the channel portion 11d. The first gate electrode 11a is made of the same first metal film 15 as for the gate wires 13, and is connected to the gate wires 13 so as to be supplied with a scan signal. The channel portion 11d is disposed to overlap the first gate electrode 11a on the upper layer-side thereof, with the first gate insulating film 16 disposed therebetween. The channel portion 11d is made of the oxide semiconductor film 17. On the upper layer-side of the channel portion 11d, the second gate insulating film 18 is stacked selectively in an area overlapping the channel portion 11d. The oxide semiconductor film 17 includes a portion overlapping the second gate insulating film 18 in which the resistance is not reduced and which forms the channel portion 11d, and a non-overlapping portion with respect to the second gate insulating film 18 which is in direct contact with the interlayer insulating film 20 and in which the resistance is reduced. Thus, at both ends in the direction of extension of the channel portion 11d, reduced-resistance regions 11e made of the oxide semiconductor film 17 and having a resistance lower than that of the channel portion 11d are disposed respectively in a continuous manner. The reduced-resistance regions 11e function as conductors having a certain resistivity (such as on the order of 1/10000000000 to 1/100 the resistivity of the channel portion 11d, which is a non-reduced-resistance region). In FIG. 4, the reduced-resistance regions 11e of the oxide semiconductor film 17 are indicated by shading.

As illustrated in FIG. 4, the source electrode 11b is disposed on the upper layer-side of the interlayer insulating film 20. The source electrode lib is made of the same third metal film 21 as for the source wires 14. The end of the source electrode lib on the channel portion 11d side with respect to the X-axis direction overlaps the first gate electrode 11a. The portion of the source electrode 11b that is non-overlapping with respect to the first gate electrode 11a is connected to one (source electrode 11b side) of the reduced-resistance regions 11e via a pixel source contact hole CH1 formed in the interlayer insulating film 20. The source electrode 11b is supplied with a data signal via the source wires 14. The drain electrode 11c is made of the same third metal film 21 as for the source wires 14 and the source electrode lib. The drain electrode 11c is disposed opposing the source electrode lib with an interval corresponding to the channel portion 11d provided therebetween. The end of the drain electrode 11c on the channel portion 11d side with respect to the X-axis direction overlaps the first gate electrode 11a. The portion of the drain electrode 11c that is non-overlapping with respect to the first gate electrode 11a is connected to the other (drain electrode 11c side) of the reduced-resistance regions 11e via a pixel drain contact hole CH2 formed in the interlayer insulating film 20. The end of the drain electrode 11c on the opposite side from the channel portion 11d side with respect to the X-axis direction is connected to the pixel electrodes 12 via a pixel contact hole CH3 formed in the planarization film 22. Thus, a charge supplied to the drain electrode 11c can be supplied to the pixel electrodes 12. The pixel TFT 11 further includes, in addition to the electrodes 11a, 11b, 11c, a second gate electrode (upper layer-side gate electrode) 11f which is made of the second metal film 19 and overlapping a part of the first gate electrode 11a with the channel portion 11d disposed therebetween. The second gate electrode 11f is disposed on the upper layer-side of the second gate insulating film 18, and has a formation area and a planar arrangement that substantially correspond to a formation area and a planar arrangement of the second gate insulating film 18. Accordingly, during manufacture, the second gate insulating film 18 is pattered along with the second metal film 19 (to remove unwanted portions by etching). The second gate electrode 11f is connected to the first gate electrode 11a via contact holes (not illustrated) formed in the first gate insulating film 16 and the second gate insulating film 18. Accordingly, the second gate electrode 11f is supplied with a signal synchronized with the first gate electrode 11a, and therefore the amount of charge circulated through the channel portion 11d is increased. As described above, the pixel TFTs 11, as opposed to the gate driver TFTs 30 as will be described later, have a single-gate structure. In the pixel TFTs 11 according to the present embodiment, the second gate insulating film 18 and the interlayer insulating film 20 stacked and formed over the channel portion 11d function as function as etch-stop layers.

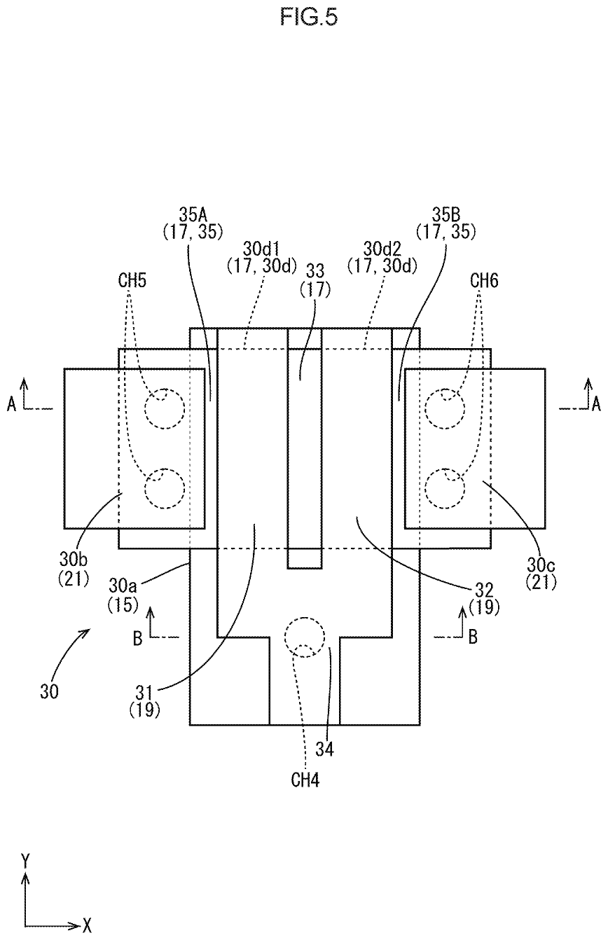

The configuration of the gate driver TFTs 30 provided in the gate driver circuit portion GDM will be described. As illustrated in FIG. 5 and FIG. 6, the gate driver TFT 30 includes at least: a first gate electrode (lower layer-side gate electrode) 30a; channel portions 30d; a source electrode 30b connected to one end side of the channel portions 30d; and a drain electrode 30c connected to another end side of the channel portions 30d. The first gate electrode 30a is made of the same first metal film 15 as for gate wires 13 and the like, and is connected to a signal input wire or a signal input terminal of the gate driver circuit portion GDM. Accordingly, the first gate electrode 30a is supplied with an input signal that is input to the gate driver circuit portion GDM. The oxide semiconductor film 17 configuring the channel portions 30d is disposed to overlap the first gate electrode 30a on the upper layer-side with the first gate insulating film 16 disposed therebetween. The oxide semiconductor film 17 extends in band-shape in the X-axis direction, and has a length of extension greater than a length dimension of the first gate electrode 30a. However, the oxide semiconductor film 17 has a width dimension smaller than a width dimension of the first gate electrode 30a. On the upper layer-side of the channel portions 30d, the second gate insulating film 18 is stacked selectively in an area overlapping the channel portions 30d. The oxide semiconductor film 17 includes a portion overlapping the second gate insulating film 18 in which the resistance is not reduced and which forms the channel portions 30d, and a portion that is non-overlapping with respect to the second gate insulating film 18 which, as will be described in detail later, is in direct contact with the interlayer insulating film 20 and in which the resistance is reduced. In FIG. 6, the reduced-resistance regions (first low-resistance portion 33 and second low-resistance portions 35) of the oxide semiconductor film 17 are indicated by shading.

As illustrated in FIG. 5 and FIG. 6, the source electrode 30b and the drain electrode 30c have substantially equal width dimensions (dimensions with respect to Y-axis direction that is the width direction) which are smaller than the width dimension of the first gate electrode 30a and the width dimension of the channel portions 30d. The source electrode 30b is disposed on the upper layer-side of the interlayer insulating film 20 and is made of the same third metal film 21 as for the source wires 14 and the like. The end of the source electrode 30b on the channel portions 30d side with respect to the X-axis direction overlapping the first gate electrode 30a. The end of the source electrode 30b on the opposite side from the channel portions 30d side with respect to the X-axis direction is connected to a signal input wire or a signal input terminal of the gate driver circuit portion GDM. Accordingly, the source electrode 30b is supplied with an input signal that is input to the gate driver circuit portion GDM. The drain electrode 30c is made of the same third metal film 21 as for the source electrode 30b and the like, and is disposed opposing the source electrode 30b with a predetermined interval (distance corresponding to the sum of the length dimensions of the two channel portions 30d and the length dimension of the first low-resistance portion 33) provided therebetween. The end of the drain electrode 30c on the channel portions 30d side with respect to the X-axis direction overlaps the first gate electrode 30a. The end of the drain electrode 30c on the opposite side from the channel portions 30d side with respect to the X-axis direction is connected to a signal output wire or a signal output terminal of the gate driver circuit portion GDM. Accordingly, an input signal supplied to the drain electrode 30c from the source electrode 30b via the channel portions 30d and the like can be output. In the gate driver TFTs 30 according to the present embodiment, as in the case of the pixel TFTs 11, the second gate insulating film 18 and the interlayer insulating film 20 stacked and formed over the channel portions 30d function as etch-stop layers.

As illustrated in FIG. 5 and FIG. 6, the gate driver TFT 30 according to the present embodiment includes a second gate electrode (upper layer-side gate electrode) 31 and an electrode 32. The second gate electrode 31 is made of the second metal film 19 and overlaps a part of the first gate electrode 30a with the channel portions 30d (source-side channel portion 30d1) disposed therebetween. The electrode 32 is made of the same second metal film 19 as for the second gate electrode 31 and overlaps a part of the first gate electrode 30a with the channel portions 30d (drain-side channel portion 30d2) disposed therebetween and is disposed with an interval provided with respect to the second gate electrode 31. The portions of the oxide semiconductor film 17 respectively overlapping the second gate electrode 31 and the electrode 32 constitute the respective channel portions 30d. The portion of the oxide semiconductor film 17 that does not overlap the second gate electrode 31 and the electrode 32 and is disposed between at least the respective channel portions 30d constitutes a first low-resistance portion (low-resistance portion) 33 having a resistance lower than that of the channel portions 30d.

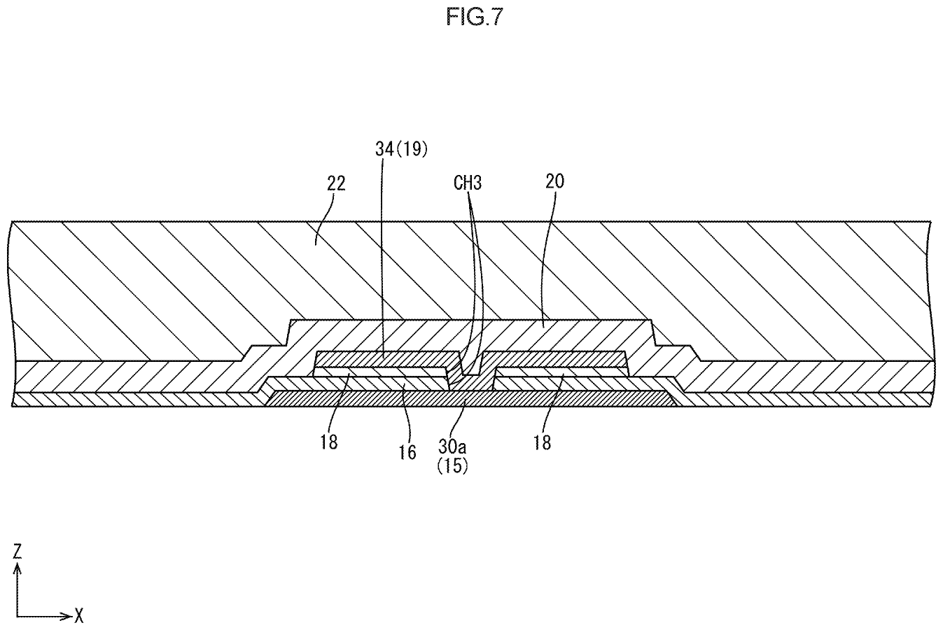

As illustrated in FIG. 5 and FIG. 6, the second gate electrode 31 overlaps the portion of the first gate electrode 30a closer to the source electrode 30b (left-side portion in FIG. 5 and FIG. 6). On the other hand, the electrode 32 overlaps the portion of the first gate electrode 30a closer to the drain electrode 30c (right-side portion in FIG. 5 and FIG. 6). The interval (distance) between the second gate electrode 31 and the electrode 32 substantially corresponds to the length dimension of the first low-resistance portion 33. As illustrated in FIG. 5 and FIG. 7, the second gate electrode 31 and the electrode 32 are connected by an electrode connecting portion 34. The electrode connecting portion 34 is made of the same second metal film 19 as for the second gate electrode 31 and the electrode 32. The electrode connecting portion 34 is displaced with respect to the Y-axis direction so as to be non-overlapping with respect to the oxide semiconductor film 17 (channel portions 30d and first low-resistance portion 33), and is connected to ends of the second gate electrode 31 and the electrode 32. In other words, the second gate electrode 31 and the electrode 32 having the branching structure connected by the electrode connecting portion 34 is formed by patterning the second metal film 19, during the manufacturing step, so as to remain in a bifurcated shape as viewed in plan. In addition, the electrode connecting portion 34 is disposed to overlap the first gate electrode 30a and is connected to the first gate electrode 30a via a gate contact hole (contact hole) CH4 formed in the first gate insulating film 16 and the second gate insulating film 18. Thus, the second gate electrode 31 and the electrode 32 are supplied with a signal synchronized with the first gate electrode 30a. Accordingly, in the present embodiment, the electrode 32 may be considered to have the same function as that of the second gate electrode 31 in the gate driver TFT 30.

As illustrated in FIG. 5 and FIG. 6, of the oxide semiconductor film 17, the two channel portions 30d respectively overlap the second gate electrode 31 and the electrode 32. The channel portions 30d overlapping the second gate electrode 31 (source-side channel portion 30d1 on the left in FIG. 5 and FIG. 6) is connected to the source electrode 30b. The channel portions 30d overlapping the electrode 32 (drain-side channel portion 30d2 on the right in FIG. 5 and FIG. 6) is connected to the drain electrode 30c. In the following, when the two channel portions 30d are distinguished, the sign for the source-side channel portion will be given a suffix “1”, and the sign for the drain-side channel portion will be given a suffix “2”. When the two channel portions 30d are not distinguished and collectively referred to, no suffixes will be given to the signs. Between the two channel portions 30d and each of the second gate electrode 31 and the electrode 32, the second gate insulating film 18 is interposed. The second gate insulating film 18 in the gate driver TFT 30 is formed with a planar arrangement and a formation area aligned (matched) with those of the two channel portions 30d (second gate electrode 31 and electrode 32). That is, the second gate insulating film 18 is patterned during manufacture such that the areas thereof overlapping the two channel portions 30d (second gate electrode 31 and electrode 32) selectively remain. The two channel portions 30d have substantially equal length dimensions.

As illustrated in FIG. 5 and FIG. 6, the first low-resistance portion 33 is formed by partially reducing the resistance of the oxide semiconductor film 17, and is stacked with the interlayer insulating film 20 directly contacting the upper layer-side thereof. The first low-resistance portion 33 functions as a conductor having a certain resistivity (such as about 1/10000000000 to 1/100 the resistivity of the channel portions 30d that is the non-reduced-resistance region). The first low-resistance portion 33 is interposed between the source-side channel portion 30d1 and the drain-side channel portion 30d2 with respect to the X-axis direction. One end side of the first low-resistance portion 33 is connected to the source-side channel portion 30d1. Another end side of the first low-resistance portion 33 is connected to the drain-side channel portion 30d2. In other words, the end of the source-side channel portion 30d1 on the opposite side from the side connected to the source electrode 30b is connected to one end side of the first low-resistance portion 33; the end of the drain-side channel portion 30d2 on the opposite side from the side connected to the drain electrode 30c is connected to the other end side of the first low-resistance portion 33.

Further, as illustrated in FIG. 5 and FIG. 6, at both ends with respect to the length direction (X-axis direction) of the oxide semiconductor film 17 extending in band-shape, second low-resistance portions 35 having a resistance lower than that of the channel portions 30d are respectively provided. The pair of second low-resistance portions 35 are the portion of the oxide semiconductor film 17 that are continuous with the other end side (source electrode 30b side or drain electrode 30c side) of the pair of channel portions 30d of which one end side is continuous with the first low-resistance portion 33. The pair of second low-resistance portions 35 is non-overlapping with respect to the second gate electrode 31 and the electrode 32. The second low-resistance portions 35 formed by partially reducing the resistance the oxide semiconductor film 17. The second low-resistance portions 35 have the interlayer insulating film 20 stacked on the upper layer-side thereof in a directly contacting manner. The second low-resistance portions 35, as in the case of the first low-resistance portion 33, function as conductors having a certain resistivity (such as about 1/10000000000 to 1/100 the resistivity of the channel portions 30d that are non-reduced-resistance regions). The pair of second low-resistance portions 35 include a source-side second low-resistance portion 35A disposed between the source electrode 30b and the first low-resistance portion 33, and a drain-side second low-resistance portions 35B disposed between the drain electrode 30c and the first low-resistance portion 33, with respect to the X-axis direction. The former is connected to the source electrode 30b, and the latter is connected to the drain electrode 30c. In the following, when the pair of second low-resistance portions 35 is distinguished, the sign for the source-side second low-resistance portion will be given a suffix “A”, and the sign for the drain-side second low-resistance portion will be given a suffix “B”. When the second low-resistance portions 35 are not distinguished and are collectively referred to, no suffixes will be given to the signs. The source-side second low-resistance portion 35A includes a portion overlapping the source electrode 30b which is connected to the source electrode 30b via a source contact hole CH5 formed in the interlayer insulating film 20. The drain-side second low-resistance portions 35B includes a portion overlapping the drain electrode 30c which is connected to the drain electrode 30c via a drain contact hole CH6 formed in the interlayer insulating film 20. The end of the source-side second low-resistance portion 35A which is on the opposite side from the source contact hole CH5 side with respect to the X-axis direction and which overlaps the first gate electrode 30a is continuous with the end of the source-side channel portion 30d1 on the opposite side from the first low-resistance portion 33 side. The end of the drain-side second low-resistance portions 35B which is on the opposite side from the drain contact hole CH6 side with respect to the X-axis direction and which overlaps the first gate electrode 30a is continuous with the end of the drain-side channel portion 30d2 on the opposite side from the first low-resistance portion 33 side.

In the gate driver TFT 30 with the above-described configuration, as a signal is supplied to the first gate electrode 30a overlapping the two channel portions 30d1, 30d2, the gate driver TFT 30 is driven and charge based on an input signal supplied to the source electrode 30b is transferred from the source electrode 30b to the first low-resistance portion 33 via the source-side second low-resistance portion 35A and the source-side channel portion 30d1 on the charge-supplying side in order. The charge is further moved from the first low-resistance portion 33 to the drain-side channel portion 30d2 on the charge-supplied side. Thereafter, the charge reaches the drain electrode 30c via the drain-side second low-resistance portions 35B. That is, the gate driver TFT 30 according to the present embodiment may be considered to have a dual-gate structure (multigate structure) in which, as opposed to the pixel TFTs 11 having the single-gate structure, two unit TFTs that are driven by the common first gate electrode 30a (second gate electrode 31 and electrode 32) are connected in series. The first low-resistance portion 33 interposed between the channel portions 30d1, 30d2 functions as a pseudo-drain electrode for one unit TFT having the source electrode 30b, and as a pseudo-source electrode for the other unit TFT having the drain electrode 30c. In the gate driver TFT 30 having the dual-gate structure, charge moves through the two channel portions 30d1, 30d2 via the first low-resistance portion 33 having a resistance lower than that of the channel portions 30d1, 30d2. Accordingly, in the vicinity of the drain electrode 30c on the charge-supplied side, the electric field concentration (so-called hot carrier phenomenon) that may be caused at the interface between the oxide semiconductor film 17 and the first gate insulating film 16 can be mitigated in a preferable manner. As a result, it becomes possible to increase the drain breakdown voltage of the gate driver TFT 30. Accordingly, even when a large potential difference is caused between the source electrode 30b and the drain electrode 30c, a failure becomes less likely to occur in the gate driver TFT 30, and the so-called drain breakdown voltage becomes high. In particular, the gate driver TFTs 30 provided in the gate driver circuit portion GDM, compared with the pixel TFTs 11 configuring the pixels PX in the display area, tend to have a high applied drain voltage (potential difference caused between the source electrode 30b and the drain electrode 30c). Thus, even when the applied drain voltage is increased by the adoption of the dual-gate structure, failure is less likely to occur and high operation reliability can be obtained. In addition, the channel portion 30d is made of the oxide semiconductor film 17 in which an oxide semiconductor material that, compared with amorphous silicon, generally has a large bandgap is used, making the drain breakdown voltage even higher.

In addition, the second gate electrode 31 is connected to the first gate electrode 30a for synchronization, and further the second gate electrode 31 is connected to the adjacent electrode 32 with an interval corresponding to the length of the first low-resistance portion 33 provided therebetween. Accordingly, the first gate electrode 30a, the second gate electrode 31, and the electrode 32 are synchronized. Thus, as a signal is supplied to the first gate electrode 30a, a synchronized signal is also supplied to the second gate electrode 31 and the electrode 32 which are connected to the first gate electrode 30a. As a result, the amount of charge circulated through the source-side channel portion 30d1 overlapping the second gate electrode 31 is increased, and the amount of charge circulated through the drain-side channel portion 30d2 overlapping the electrode 32 is also increased. In this way, the decrease in drain current due to an increase in the length of the charge circulation route resulting from the double channel portions 30d suppressed.

The second gate electrode 31 and the electrode 32 are both made of the second metal film 19 and are disposed to overlap the two channel portions 30d1, 30d2. In this case, a charge may be drawn to the film interface of the planarization film 22 due to ON/OFF operation of the gate driver TFT 30, for example, and the charge may be diffused in the planarization film 22, resulting in charge at the interface between the planarization film 22 and the interlayer insulating film 20. If, due to the charge, a so-called back channel is formed in the channel portions 30d1, 30d2, leak current may be generated, and the operation reliability of the gate driver TFT 30 may be adversely affected. In this respect, the second gate electrode 31 and the electrode 32 made of the second metal film 19 is disposed to overlap the channel portions 30d1, 30d2 via the second gate insulating film 18. Accordingly, even if a charge is generated on the upper layer-side of the second metal film 19 as described above, an electric field due to the charge will be blocked by the second gate electrode 31 and the electrode 32, making the formation of a back channel in the channel portions 30d1, 30d2 difficult. In this way, sufficiently high operation reliability of the gate driver TFTs 30 can be maintained.

The first low-resistance portion 33 is made of the portion of the oxide semiconductor film 17 which is non-overlapping with respect to the second gate electrode 31 and the electrode 32 and which is disposed between the at least two channel portions 30d1, 30d2. Accordingly, it is possible, during manufacture, to provide the first low-resistance portion 33 by partially reducing the resistance of the oxide semiconductor film 17 by utilizing the arrangement of the second gate electrode 31 and the electrode 32. Specifically, the portion of the oxide semiconductor film 17 which is non-overlapping with respect to the second gate electrode 31 and the electrode 32 and which is disposed between the at least two channel portions 30d1, 30d2 is in direct contact with the interlayer insulating film 20, which is formed on the upper layer-side during manufacture. The interlayer insulating film 20 includes a layer made of silicon nitride at least on the lower layer side (the side contacting the oxide semiconductor film 17), the layer containing hydrogen. Accordingly, in the portion of the oxide semiconductor film 17 that directly contacts the interlayer insulating film 20, the hydrogen included in the interlayer insulating film 20 is diffused, thereby reducing the resistance of the portion. In this way, it becomes possible to obtain a non-overlapping arrangement between the second gate electrode 31 and the electrode 32 and the first low-resistance portion 33 in a self-aligning manner, whereby the parasitic capacitance that could be introduced therebetween can be stably reduced. Thus, the second gate electrode 31 and the electrode 32 and the first low-resistance portion 33 are disposed in a non-overlapping arrangement in a self-aligning manner, and the arrangement is not influenced by exposure displacement and the like of a photomask used during manufacture. Accordingly, it becomes possible to use a photomask of which the exposure accuracy is not extremely high, and thereby to reduce manufacturing cost.

In addition, in the portions of the oxide semiconductor film 17 that are continuous with the other end sides of the pair of channel portions 30d1, 30d2 of which one end sides are continuous with the first low-resistance portion 33, the second low-resistance portions 35A, 35B are respectively provided in which the resistance is lower than that of the channel portions 30d1, 30d2. Accordingly, during manufacture, it is possible to provide the pair of second low-resistance portions 35A, 35B, in addition to the first low-resistance portion 33, by partially reducing the resistance of the oxide semiconductor film 17 by utilizing the arrangement of the second gate electrode 31 and the electrode 32. Specifically, the pair of portions of the oxide semiconductor film 17 that are non-overlapping with respect to the second gate electrode 31 and the electrode 32 and that are on the opposite side from the first low-resistance portion 33 side with respect to the second gate electrode 31 and the electrode 32 are in direct contact with the interlayer insulating film 20 formed on the upper layer-side during manufacture. The interlayer insulating film 20 includes a layer made of silicon nitride at least on the lower layer side (the side contacting the oxide semiconductor film 17), the layer containing hydrogen. Accordingly, in the pair of portions of the oxide semiconductor film 17 that directly contact the interlayer insulating film 20, the hydrogen included in the interlayer insulating film 20 is diffused, reducing the resistance of the pair of portions. In this way, it becomes possible to obtain the non-overlapping arrangement between the second gate electrode 31 and the electrode 32 and the first low-resistance portion 33 and pair of second low-resistance portions 35A, 35B in a self-aligning manner. As a result, it becomes possible to stably reduce the parasitic capacitance that could be introduced between the second gate electrode 31 and the electrode 32 and the first low-resistance portion 33 and the pair of second low-resistance portions 35A, 35B.

The gate driver TFTs 30 according to the present embodiment have the above-described structure. In the following, a method of producing the gate driver TFTs 30 will be described. The method of producing the gate driver TFTs 30 includes: a first gate electrode forming step of forming the first gate electrode 30a; a first gate insulating film forming step (first insulating film forming step) of forming the first gate insulating film 16; an oxide semiconductor film forming step of patterning the oxide semiconductor film 17; a second gate insulating film forming step (second insulating film forming step) of forming the second gate insulating film 18; a second gate electrode and electrode forming step of forming the second gate electrode 31 and the electrode 32; an interlayer insulating film forming step/low-resistance portion forming step (third insulating film forming step/low-resistance portion forming step) of forming the interlayer insulating film 20 and forming the first low-resistance portion 33 and the second low-resistance portions 35; a source electrode and drain electrode forming step of forming the source electrode 30b and the drain electrode 30c; and a planarization film forming step of forming the planarization film 22. By the method of producing the gate driver TFTs 30, various films are patterned to simultaneously manufacture the pixel TFTs 11. A method of producing the array substrate 10b includes the method of producing the gate driver TFTs 30, and includes a step of forming the pixel electrodes 12 by patterning the transparent electrode film 23 and a step of forming the alignment film 10e.

In the first gate electrode forming step, on a glass substrate GS that forms the array substrate 10b, the first metal film 15 and a photoresist are successively formed. Then, after the photoresist is exposed and developed using the photomask, etching is performed to pattern the first metal film 15, forming the first gate electrode 30a. In this case, during the patterning of the first metal film 15, the gate wires 13 and the first gate electrode 11a and the like of the pixel TFTs 11 are also formed. In the first gate insulating film forming step, the first gate insulating film 16 is formed as a solid film on the glass substrate GS and the first metal film 15.

In the oxide semiconductor film forming step, the oxide semiconductor film 17 and a photoresist are successively formed on the first gate insulating film 16. After the photoresist is exposed and developed using a photomask, etching is performed to perform patterning such that a band-shaped portion extending in the X-axis direction and overlapping the first gate electrode 30a remains. The band-shaped portion includes the channel portions 30d and the low-resistance portions 33, 35 of which the resistance is yet to be reduced.

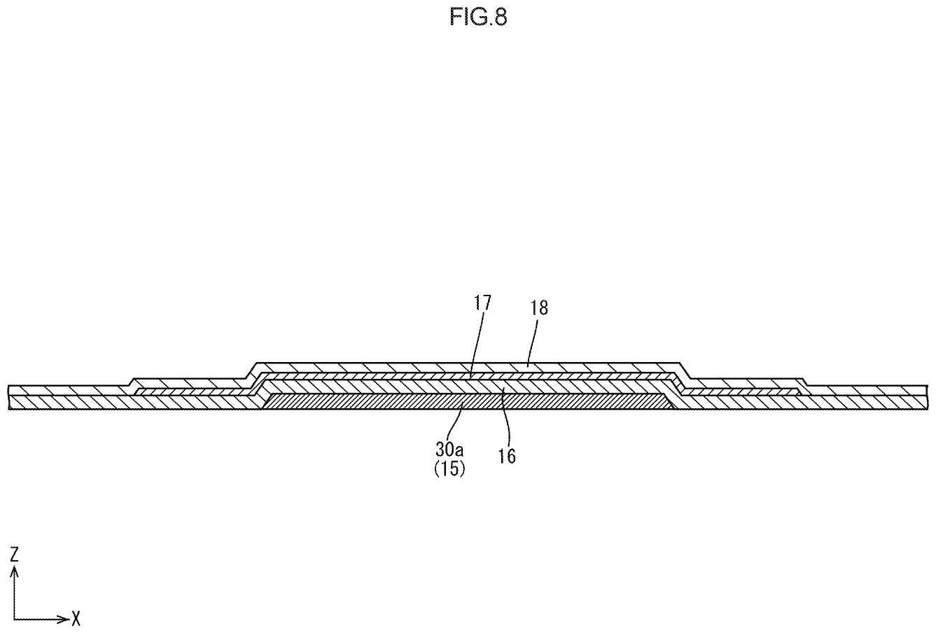

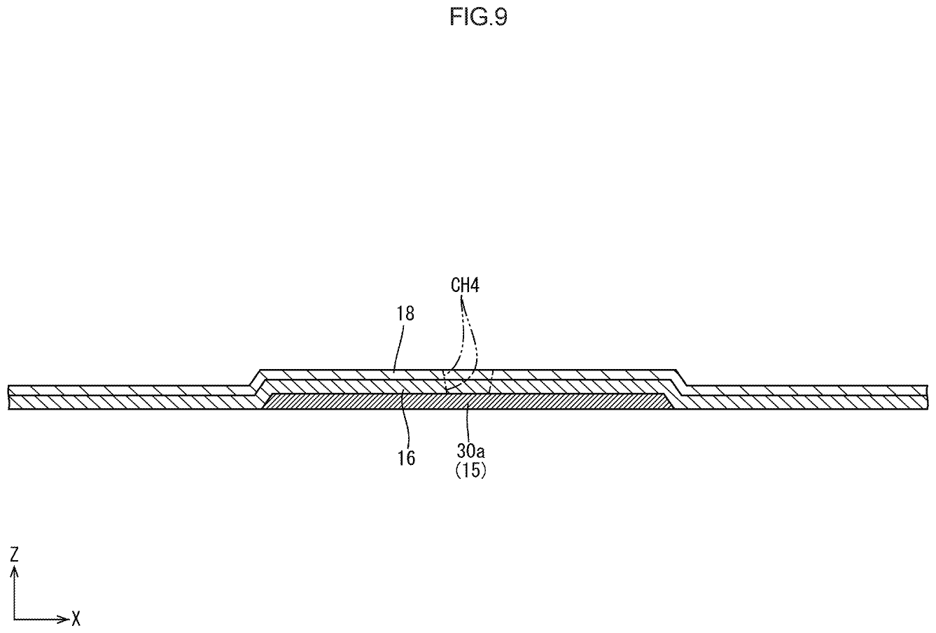

As illustrated in FIG. 8 and FIG. 9, in the second gate insulating film forming step, the second gate insulating film 18 and a photoresist are successively formed on the first gate insulating film 16 and the oxide semiconductor film 17. After the photoresist is exposed and developed using a photomask, etching is performed. In this case, the second gate insulating film 18 and the first gate insulating film 16 are patterned in one go, whereby the gate contact hole CH4 is formed in a position overlapping the first gate electrode 30a. In FIG. 9, the gate contact hole CH4 is illustrated by dashed and double-dotted line.

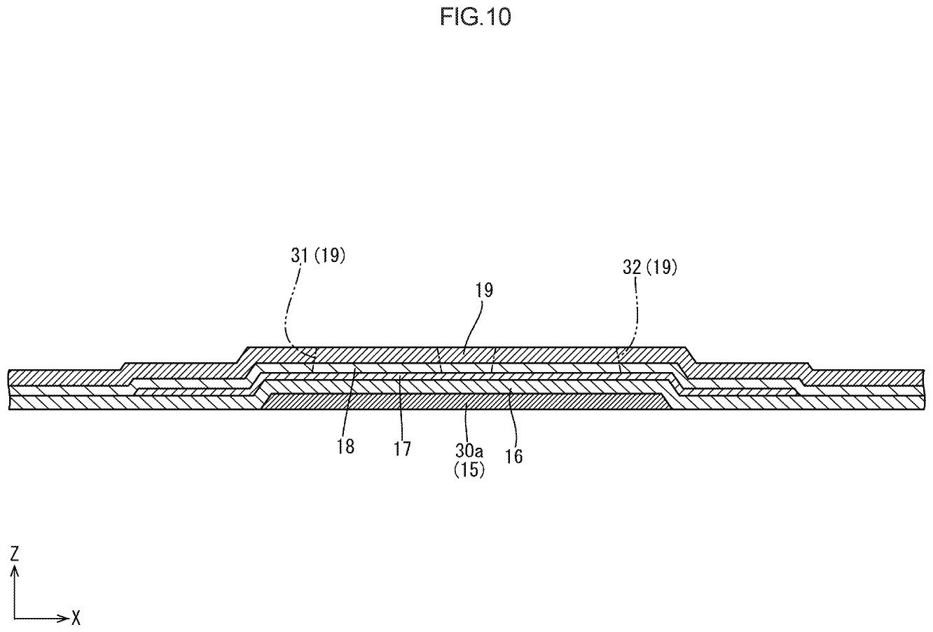

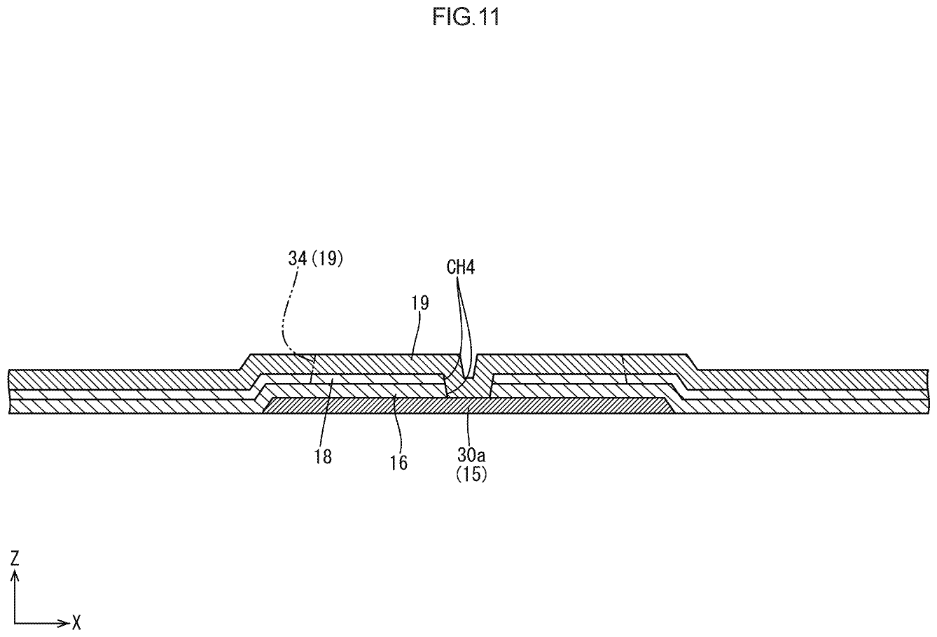

As illustrated in FIG. 10 and FIG. 11, in the second gate electrode and the electrode forming step, the second metal film 19 and a photoresist are successively formed on the second gate insulating film 18. After the photoresist is exposed and developed using a photomask, etching is performed to pattern the second metal film 19, forming the second gate electrode 31 and the electrode 32 and also forming the electrode connecting portion 34 connecting the second gate electrode 31 and the electrode 32. In the second gate electrode and the electrode forming step, when the etching is performed, in addition to the portion to be removed of the second metal film 19, etching is also performed with respect to the portion to be removed of the second gate insulating film 18 in one go, and, of the second gate insulating film 18, the entire portion that is to be non-overlapping with respect to the remaining portions (the second gate electrode 31 and the electrode 32) of the second metal film 19 is removed together with the portion to be removed of the second metal film 19. During formation of the second metal film 19, the electrode connecting portion 34 of the second metal film 19 is connected to the first gate electrode 30a via the gate contact hole CH4 (FIG. 11). In the second gate electrode and the electrode forming step, together with the patterning of the second metal film 19, the second gate electrode 11f and the like of the pixel TFTs 11 is also formed. During etching, of the second gate insulating film 18, the entire portions that are to be non-overlapping with respect to the remaining portion (second gate electrode 11f) of the second metal film 19 are removed together with the portions to be removed of the second metal film 19 (see FIG. 4). In FIG. 10 and FIG. 11, the boundaries between the removed portions and the remaining portions of the second gate insulating film 18 and the second metal film 19 are illustrated by dashed and double-dotted line.

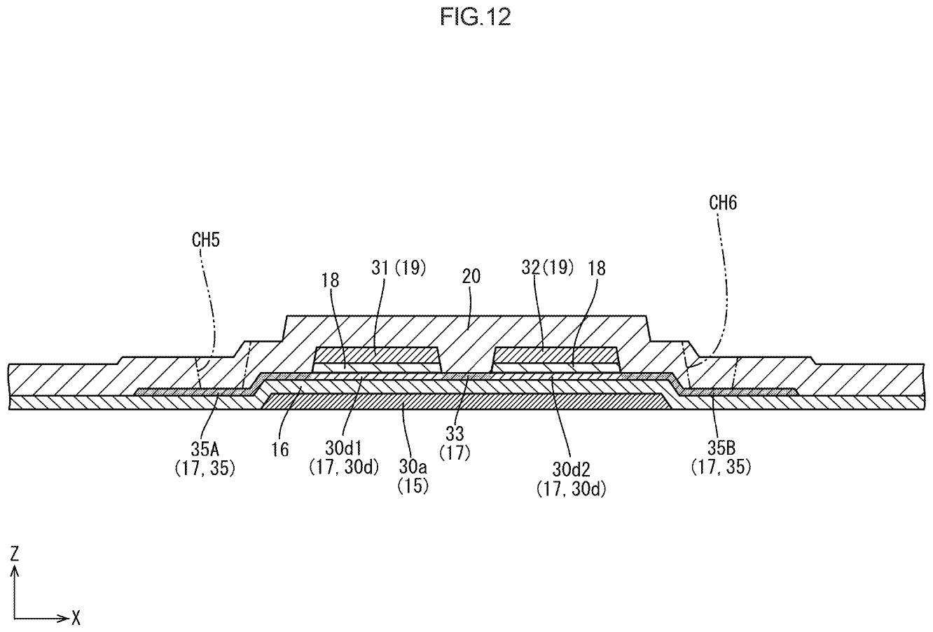

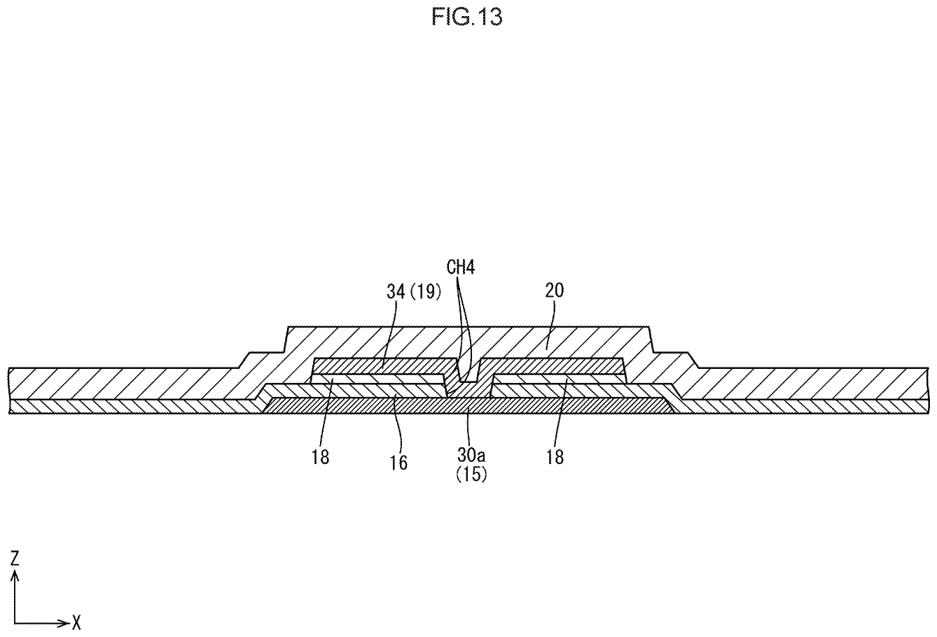

As illustrated in FIG. 12 and FIG. 13, in the interlayer insulating film forming step/low-resistance portion forming step, the interlayer insulating film 20 is formed as a solid film on the second metal film 19, the oxide semiconductor film 17, and the first gate insulating film 16. In FIG. 12 and FIG. 13, illustration of the layer structure of the interlayer insulating film 20 is omitted. In practice, the interlayer insulating film 20 is configured of two layers of laminated films made of inorganic material, such as silicon oxide (SiO₂) or silicon nitride (SiNₓ), as described above. Accordingly, in the interlayer insulating film forming step/low-resistance portion forming step, as the layer on the lowest layer side of the interlayer insulating film 20 that contacts the oxide semiconductor film 17, a layer made of silicon nitride is formed. The layer made of silicon nitride contains hydrogen in the material thereof. Thus, in the portion of the oxide semiconductor film 17 that contacts the layer, hydrogen is diffused and a decrease in resistance is promoted. In this case, the portions of the oxide semiconductor film 17 that overlap the second gate electrode 31 and the electrode 32 (second gate insulating film 18) do not directly contact the interlayer insulating film 20, and are therefore not subjected to a decrease in resistance. Meanwhile, the portions of the oxide semiconductor film 17 that do not overlap the second gate electrode 31 and the electrode 32 (second gate insulating film 18) directly contact the interlayer insulating film 20, and are therefore subjected to a decrease in resistance. In this way, of the oxide semiconductor film 17, the portion disposed between the second gate electrode 31 and the electrode 32 forms the first low-resistance portion 33. On the other hand, the portions continuous with the other end sides of the pair of channel portions 30d of which the one end sides are continuous with the first low-resistance portion 33 respectively form the second low-resistance portions 35. Thereafter, a film of photoresist is formed on the interlayer insulating film 20. After the photoresist is exposed and developed using a photomask, etching is performed to form the source contact hole CH5 and the drain contact hole CH6 in the positions respectively overlapping the pair of second low-resistance portions 35. In the interlayer insulating film forming step/low-resistance portion forming step, with respect to the pixel TFTs 11, during the formation of the interlayer insulating film 20, the portion of the oxide semiconductor film 17 overlapping the second gate electrode 11f (second gate insulating film 18) does not directly contact the interlayer insulating film 20, and is therefore not subjected to a decrease in resistance. However, the portions that do not overlap the second gate electrode 11f (second gate insulating film 18) directly contact the interlayer insulating film 20, and are therefore subjected to a decrease in resistance, forming the reduced-resistance regions 11e (see FIG. 4). In FIG. 12, the gate contact hole CH4 is illustrated by dashed and double-dotted line.

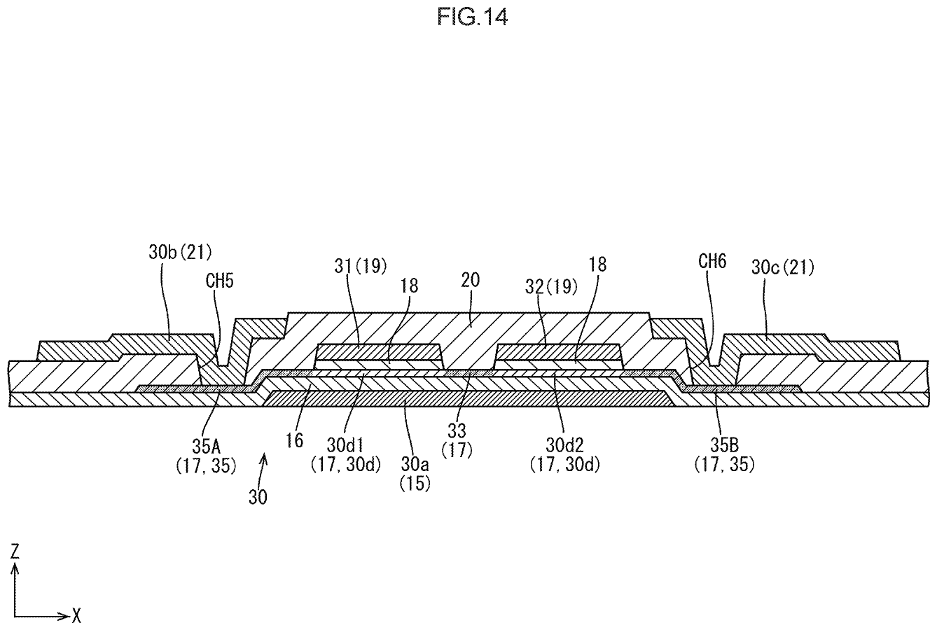

As illustrated in FIG. 14, in the source electrode and drain electrode forming step, the third metal film 21 and a photoresist are successively formed on the interlayer insulating film 20. After the photoresist is exposed and developed using a photomask, etching is performed, whereby the third metal film 21 is patterned and the source electrode 30b and the drain electrode 30c are formed. The source electrode 30b is connected to the source-side second low-resistance portion 35A via the source contact hole CH5. The drain electrode 30c is connected to the drain-side second low-resistance portions 35B via the drain contact hole CH6. In the source electrode and drain electrode forming step, with respect to the pixel TFTs 11, together with the patterning of the third metal film 21, the source electrode 11b and the drain electrode 11c are formed (see FIG. 4). Subsequently, in the planarization film forming step, the planarization film 22 is formed as a solid film on the interlayer insulating film 20 and the third metal film 21.

Thus, it is possible to provide the first low-resistance portion 33 and the second low-resistance portions 35 respectively by partially reducing the resistance of the oxide semiconductor film 17 by utilizing the arrangement of the second gate electrode 31 and the electrode 32. Accordingly, the non-overlapping arrangement between the second gate electrode 31 and the electrode 32 and the first low-resistance portion 33 and the second low-resistance portions 35 can be obtained in a self-aligning manner and, consequently, the parasitic capacitance that could be introduced therebetween can be stably reduced.

As described above, the gate driver TFT (thin-film transistor) 30 according to the present embodiment includes the first metal film (first electrically conductive film) 15, the oxide semiconductor film (semiconductor film) 17 disposed on the upper layer-side of the first metal film 15 with the first gate insulating film (first insulating film) 16 disposed therebetween, the second metal film (second electrically conductive film) 19 disposed on the upper layer-side of the oxide semiconductor film 17 with the second gate insulating film (second insulating film) 18 disposed therebetween, the first gate electrode 30a formed from the first metal film 15, the second gate electrode 31 formed from the second metal film 19 and overlapping a part of the first gate electrode 30a, the electrode 32 formed from the second metal film 19, overlapping a part of the first gate electrode 30a, and disposed away from the second gate electrode 31 at an interval, channel portions 30d formed from the oxide semiconductor film 17 that respectively overlap the second gate electrode 31 and the electrode 32, and the first low-resistance portion (low-resistance portion) 33 formed from the oxide semiconductor film 17 that is non-overlapping with respect to the second gate electrode 31 and the electrode 32 and that is disposed between at least a plurality of channel portions 30d, the first low-resistance portion 33 having a resistance lower than that of the channel portions 30d.

In this way, as a signal is supplied to the first gate electrode 30a overlapping the plurality of the channel portions 30d, charge is transferred from the channel portions 30d on the charge-supplying side to the first low-resistance portion 33, and from the first low-resistance portion 33 to the channel portions 30d on the charge-supplied side. Thus, the charge moves through the plurality of channel portions 30d via the first low-resistance portion 33 of which the resistance is lower than that of the channel portions 30d. Accordingly, it becomes possible to preferably mitigate the electric field concentration caused at the interface between the oxide semiconductor film 17 and the first gate insulating film 16 on the charge-supplied side, whereby the breakdown voltage of the gate driver TFTs 30 can be increased. In addition, the second gate electrode 31 is also supplied with a signal, increasing the amount of charge circulated through the channel portion 30d overlapping the second gate electrode 31. In this way, a decrease in current caused by an increase in the length of the charge circulation route due to a plurality of the channel portions 30d can be suppressed.

The second gate electrode 31 and the electrode 32 are both formed from the second metal film 19 and disposed to overlap the plurality of channel portions 30d. Accordingly, even if charge is generated on the upper layer-side of the second metal film 19, an electric field due to the charge is blocked by the second gate electrode 31 and the electrode 32, making the formation in the channel portions 30d of a back channel due to the electric field difficult. As a result, sufficiently high operation reliability of the gate driver TFTs 30 can be maintained.

The first low-resistance portion 33 is formed from the portion of the oxide semiconductor film 17 that is non-overlapping with respect to the second gate electrode 31 and the electrode 32 and that is disposed between at least a plurality of channel portions 30d. Accordingly, it is possible, during manufacture, to provide the first low-resistance portion 33 by partially reducing the resistance of the oxide semiconductor film 17 by utilizing the arrangement of the second gate electrode 31 and the electrode 32. In this way, it becomes possible to obtain the non-overlapping arrangement between the second gate electrode 31 and the electrode 32 and the first low-resistance portion 33 in a self-aligning manner, and to stably reduce the parasitic capacitance that could be introduced therebetween.

In the portions of the oxide semiconductor film 17 that are continuous to the other end sides of the pair of channel portions 30d of which one end sides are continuous to the first low-resistance portion 33, the second low-resistance portions 35 that are non-overlapping with respect to the second gate electrode 31 and the electrode 32 and that have a resistance lower than that of the channel portions 30d are respectively provided. In this way, it is possible, during manufacture, to provide the pair of second low-resistance portions 35, in addition to the first low-resistance portion 33, by partially reducing the resistance of the oxide semiconductor film 17 by utilizing the arrangement of the second gate electrode 31 and the electrode 32. In this way, it becomes possible to obtain the non-overlapping arrangement between the second gate electrode 31 and the electrode 32 and the first low-resistance portion 33 and pair of second low-resistance portions 35 in a self-aligning manner. As a result, the parasitic capacitance that could be introduced between the second gate electrode 31 and the electrode 32 and the first low-resistance portion 33 and pair of second low-resistance portions 35 can be stably reduced.

The semiconductor film is formed of the oxide semiconductor film 17. In this way, compared with amorphous silicon, generally a greater bandgap is obtained. Accordingly, when the semiconductor film is the oxide semiconductor film 17, it becomes possible to further increase the breakdown voltage of the gate driver TFTs 30.

The interlayer insulating film (third insulating film) 20 is disposed on the upper layer-side of the second metal film 19 and made of material containing hydrogen. In this way, the hydrogen contained in the material of the interlayer insulating film 20 is diffused into the portions of the oxide semiconductor film 17 that do not overlap the second gate electrode 31 and the electrode 32, and the portions are reduced in resistance.

The second gate electrode 31 is connected to the first gate electrode 30a via the gate contact hole (contact hole) CH4 formed in the first gate insulating film 16 and the second gate insulating film 18. In this way, the signal supplied to the first gate electrode 30a is also supplied to the second gate electrode 31 via the gate contact hole CH4. Accordingly, it is possible to easily synchronize the first gate electrode 30a and the second gate electrode 31.

The electrode 32 is connected to the second gate electrode 31. In this way, the electrode 32 is supplied with a signal synchronized with the first gate electrode 30a and the second gate electrode 31. Accordingly, the amount of charge circulated through the channel portion 30d overlapping the electrode 32, in addition to that through the channel portion 30d overlapping the second gate electrode 31, is increased.

The method of producing the gate driver TFTs 30 according to the present embodiment includes: the first gate electrode forming step of forming the first gate electrode 30a by forming the first metal film 15 and patterning the a first metal film 15; the first gate insulating film forming step (first insulating film forming step) of forming the first gate insulating film 16 on the upper layer-side of the first metal film 15; the oxide semiconductor film forming step of forming the oxide semiconductor film 17 on the upper layer-side of the first gate insulating film 16 and patterning the oxide semiconductor film 17; the second gate insulating film forming step (second insulating film forming step) of forming the second gate insulating film 18 on the upper layer-side of the oxide semiconductor film 17; the second gate electrode and the electrode forming step of forming the second metal film 19 on the upper layer-side of the second gate insulating film 18, patterning the formed second metal film 19 to form the second gate electrode 31 overlapping a part of the first gate electrode 30a and the electrode 32 overlapping a part of the first gate electrode 30a and disposed away from the second gate electrode 31 at an interval, and removing the portions of the second gate insulating film 18 that do not overlap the second gate electrode 31 and the electrode 32; and the interlayer insulating film forming step/low-resistance portion forming step (third insulating film forming step/low-resistance portion forming step) of forming the interlayer insulating film 20 made of material containing hydrogen on the upper layer-side of the second metal film 19 according to the forming of the interlayer insulating film 20, forming the first low-resistance portion 33 included in the portion of the oxide semiconductor film 17 that does not overlap the second gate electrode 31 and the electrode 32, the first low-resistance portion 33 having a resistance lower than that of the plurality of channel portions 30d made of the portions of the oxide semiconductor film 17 that overlap the second gate electrode 31 and the electrode 32.

When, after the first gate electrode forming step, the first gate insulating film forming step, the oxide semiconductor film forming step, and the second gate insulating film forming step, the second gate electrode and the electrode forming step is performed, the second gate electrode 31 made of the second metal film 19 and overlapping a part of the first gate electrode 30a, and the electrode 32 made of the second metal film 19, overlapping a part of the first gate electrode 30a, and disposed with an interval provided with respect to the second gate electrode 31 are formed. In this case, the portions of the second gate insulating film 18 that do not overlap the second gate electrode 31 and the electrode 32 are removed. In the subsequent interlayer insulating film forming step/first low-resistance portion forming step, the interlayer insulating film 20 made of material containing hydrogen is formed on the upper layer-side of the second metal film 19. In this case, in the portion of the oxide semiconductor film 17 that does not overlap the second gate electrode 31 and the electrode 32, the hydrogen contained in the material of the interlayer insulating film 20 is diffused, whereby the resistance of the portion is reduced. As a result, the first low-resistance portion 33 having a resistance lower than that of the plurality of channel portions 30d made of the portions of the oxide semiconductor film 17 that overlap the second gate electrode 31 and the electrode 32 is formed.

Thus, the first low-resistance portion 33 can be provided by partially reducing the resistance of the oxide semiconductor film 17 by utilizing the arrangement of the second gate electrode 31 and the electrode 32. Accordingly, it becomes possible to obtain the non-overlapping arrangement between the second gate electrode 31 and the electrode 32 and the first low-resistance portion 33 in a self-aligning manner, thereby stably reducing the parasitic capacitance that could be introduced therebetween.

### Second Embodiment

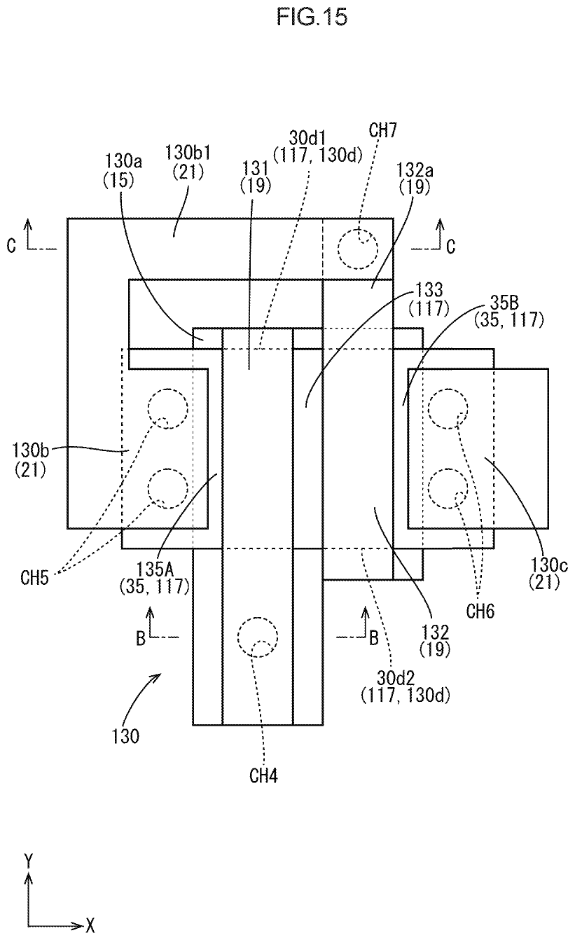

The second embodiment of the present invention will be described with reference to FIG. 15 to FIG. 17. In the second embodiment, an electrode 132 is connected to a component different from that of the first embodiment. Descriptions of structures, operations, and effects similar to those of the first embodiment will not be described.

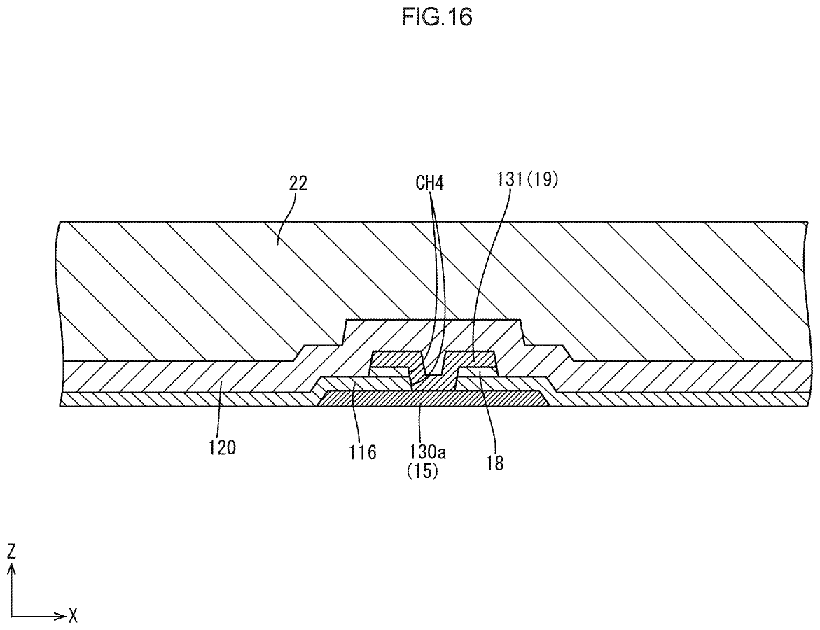

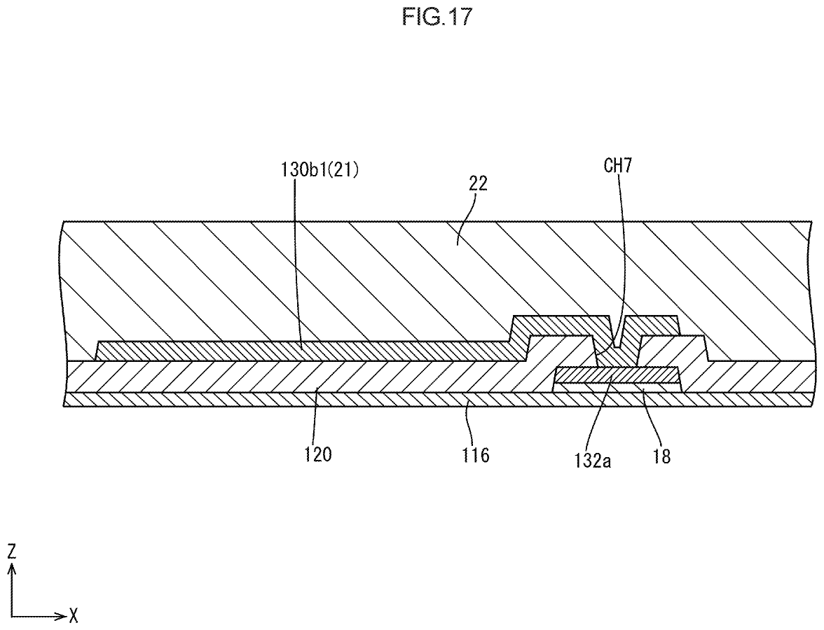

As illustrated in FIG. 15 to FIG. 17, in a gate driver TFT 130 according to the present embodiment, a second gate electrode 131 is connected to a first gate electrode 130a, whereas the electrode 132 is connected to a source electrode 130b. As illustrated in FIG. 15 and FIG. 16, the second gate electrode 131 extends with one end thereof with respect to the Y-axis direction not overlapping the oxide semiconductor film 117, the extending portion overlapping the first gate electrode 130a and being connected to the first gate electrode 130a via the gate contact hole CH4. On the other hand, as illustrated in FIG. 15 and FIG. 17, the electrode 132 extends with the other end thereof with respect to the Y-axis direction (the end on the opposite side from the side of the extending portion of the second gate electrode 131) not overlapping with respect to the oxide semiconductor film 117, the extending portion 132a overlapping the source electrode 130b and being connected to the source electrode 130b via an electrode contact hole CH7. The source electrode 130b includes a substantially L-shaped extending portion 130b1 which extends, from the end of the oxide semiconductor film 117 on the opposite side from the side of the location (source contact hole CH5) for connection with the source-side second low-resistance portion 135A, in the same orientation as the extending portion 132a of the electrode 132 along the Y-axis direction, and which further extends in the X-axis direction toward the drain electrode 130c side, the distal end of the extending portion overlapping the extending portion 132a of the electrode 132. The electrode contact hole CH7 is formed in the interlayer insulating film 120 at the position overlapping the extending portions 130b1, 132a of the electrode 132 and the source electrode 130b. In this configuration, the electrode 132 is supplied with a signal synchronized with the source electrode 130b. Accordingly, it becomes possible to further preferably mitigate the electric field concentration caused at the interface between the oxide semiconductor film 117 and the first gate insulating film 116 in the vicinity of the drain electrode 130c on the charge-supplied side. As a result, it becomes possible to increase the drain breakdown voltage of the gate driver TFT 130.

As described above, according to the present embodiment, the source electrode 130b is connected to the other end side of the channel portion 130d of which one end side is continuous with the first low-resistance portion 133, and the electrode 132 is connected to the source electrode 130b. In this way, the electrode 132 is supplied with a signal synchronized with the source electrode 130b. Accordingly, it is possible to further preferably mitigate the electric field concentration caused at the interface between the oxide semiconductor film 117 and the first gate insulating film 116 on the charge-supplied side.

### Third Embodiment

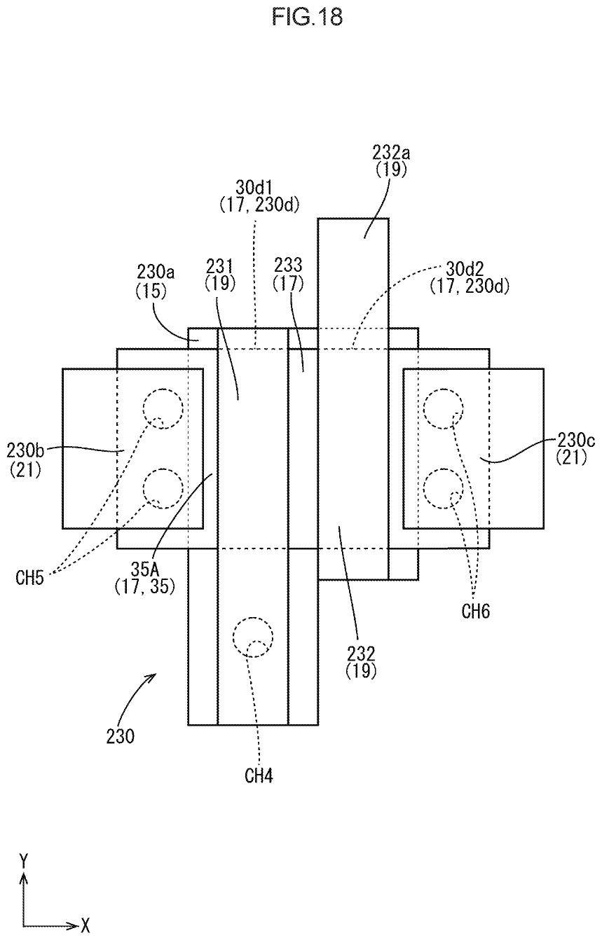

The third embodiment of the present invention will be described with reference to FIG. 18. In the third embodiment, an electrode 232 is connected to a component different from that of the second embodiment. Descriptions of structures, operations, and effects similar to those of the second embodiment will not be described.

As illustrated in FIG. 18, in a gate driver TFT 230 according to the present embodiment, the second gate electrode 231 is connected to a first gate electrode 230a, whereas an extending portion 232a of the electrode 232 is connected to a signal supply source (not illustrated) other than the electrodes 230a, 230b, 230c, 231 configuring the gate driver TFT 230. The electrode 232 is supplied with a signal of a voltage lower than a voltage applied from the connected signal supply source to the source electrode 230b. As the electrode 232 is supplied with the signal of a voltage lower than a voltage applied to the source electrode 230b, a threshold voltage relating to the gate driver TFT 230 is increased. In this way, it is possible to reduce the current that can flow through respective channel portions 230d in a state in which no signal is being supplied to the first gate electrode 230a and the second gate electrode 231. The source electrode 230b does not include the extending portion 130b1 described in the second embodiment.

As described above, according to the present embodiment, the source electrode 230b is connected to the other end side of the channel portions 230d of which one end side is continuous with the first low-resistance portion 233, and the electrode 232 is supplied with a signal of a voltage lower than a voltage applied to the source electrode 230b. As the electrode 232 is supplied with the signal of a voltage lower than a voltage applied to the source electrode 230b, a threshold voltage relating to the gate driver TFT 230 is increased. In this way, it becomes possible to reduce the current that can flow through the channel portions 230d in a state in which no signal is being supplied to the first gate electrode 230a and the second gate electrode 231.

### Other Embodiments

The present invention is not limited to the embodiments described above and illustrated in the drawings, and may include the following exemplary embodiments in the technical scope of the present invention.

(1) In the foregoing embodiments, a gate driver TFT having a dual-gate structure in which two unit TFTs are connected in series has been described by way of example. However, the present invention is applicable to a gate driver TFT having a triple-gate structure (multigate structure) in which three unit TFTs are connected in series. The present invention is also applicable to a gate driver TFT having a multigate structure in which four or more unit TFTs are connected in series. Thus, when the number of unit TFTs connected in series is three or more, the number of first low-resistance portions that are installed may be increased to a plurality of numbers, where the number installed is a value obtained by subtracting one from the number of unit TFTs connected in series.

(2) In the foregoing embodiments, the case has been described in which the respective low-resistance portions are formed by a decrease in resistance that is promoted by the diffusion of hydrogen contained in the material of the interlayer insulating film into the oxide semiconductor film. However, the respective low-resistance portions may be formed by, for example, promoting a decrease in resistance in the portions of the oxide semiconductor film that do not overlap the second gate insulating film and the second gate electrode and the electrode, through a resistance reducing process, such as a plasma process or a vacuum anneal process, after the second gate electrode and the electrode forming step is performed during manufacture of the gate driver TFT. In this case, it is possible to use a material of the interlayer insulating film that does not contain hydrogen.

(3) In the foregoing embodiments, the configuration has been indicated in which the oxide semiconductor film includes the first low-resistance portion and a pair of second low-resistance portions. However, a configuration may be adopted in which the oxide semiconductor film only includes the first low-resistance portion, and the second low-resistance portions are not provided.

(4) In the foregoing embodiments, the case has been described in which the source electrode and the drain electrode are made of the third metal film on the upper layer-side of the interlayer insulating film. However, it is also possible to adopt a configuration in which the source electrode and the drain electrode are made of the second metal film on the lower layer side of the interlayer insulating film.

(5) In the foregoing embodiments, the case has been described in which the two channel portions have equal length dimensions, it is possible to vary the length dimensions of the two channel portions.

(6) In a modification of the foregoing embodiments, the first gate electrode may have a branching structure of which one branch portion is disposed to overlap the second gate electrode and the other branch portion is disposed to overlap the electrode, and the first gate electrode may be disposed to be non-overlapping or partially overlapping with respect to the first low-resistance portion. In this way, it is possible to reduce the parasitic capacitance introduced between the first gate electrode and the first low-resistance portion.

(7) In the foregoing embodiments, the case has been described in which the source wire is formed from the third metal film. However, it is also possible to form the source wire from the second metal film.

(8) In the foregoing embodiments, an array substrate having an oxide semiconductor film as a semiconductor film has been described by way of example. It is also possible to use other materials for the semiconductor film, such as continuous grain (CG) silicon which is a type of polysilicon (polycrystallized silicon (polycrystalline silicon), or amorphous silicon.

(9) The specific materials of insulating films, such as the gate insulating film, the interlayer insulating film, and the planarization film, may be modified, as appropriate, from those described in the foregoing embodiments.

(10) The specific materials of metal films, such as the first metal film, the second metal film, and the third metal film may be modified, as appropriate, from those described in the foregoing embodiments. The laminated structure of the metal films may also be modified, as appropriate. For example, the number of stacks may be modified, a single-layer structure may be adopted, or an alloy structure may be adopted.

(11) The specific transparent electrode material used in the transparent electrode film may be modified, as appropriate, from that of the foregoing embodiments. Specifically, a transparent electrode material such as indium tin oxide (ITO) or zinc oxide (ZnO) may be used.

(12) In the foregoing embodiments, the case has been described in which, in a liquid crystal panel having a VA mode as an operation mode, only one layer of a transparent electrode film is provided on an array substrate. However, two layers of transparent electrode films may be provided with an interlayer insulating film disposed therebetween. In this case, it is possible, for example, for one transparent electrode film to configure a pixel electrode and the other transparent electrode film to configure an auxiliary capacity electrode for forming a capacitance between the auxiliary capacity electrode and the pixel electrode.

(13) In the foregoing embodiments, the liquid crystal panel has been described by way of example in which the operation mode is a VA mode. However, the present invention is also applicable to the gate driver TFT of a liquid crystal panel having other operation modes, such as an in-plane switching (IPS) mode or a fringe field switching (FFS) mode.

(14) In the foregoing embodiments, examples have been described in which the liquid crystal panel pixels have the three colors of red, green, and blue. However, the present invention is also applicable to a gate driver TFT of a liquid crystal panel provided with pixels of four colors including yellow, for example, as well as red, green, and blue.

(15) The present invention also includes the liquid crystal panel according to the foregoing embodiments to which a functional panel, such as a touch panel or a parallax barrier panel (switch liquid crystal panel) can be attached in a stacked manner.

(16) In the foregoing embodiments, a gate driver TFT provided in a liquid crystal panel has been described by way of example. However, the present invention is also applicable to a gate driver TFT provided in other types of display panel (such as an organic EL panel, a plasma display panel (PDP), an electrophoretic display (EPD) panel, and a micro electromechanical systems (MEMS) display panel.

(17) In the foregoing embodiments, the case has been described in which the pixel TFT configuring a pixel in the display region has a single-gate structure. However, the pixel TFT may have a dual-gate structure (multigate structure) having a second gate electrode and electrode and a first low-resistance portion and the like, as in the case of the gate driver TFT. Also, the pixel TFT may have conventional dual-gate structure. All of the gate driver TFTs provided in the gate driver circuit portion may have the dual-gate structure having the second gate electrode and the electrode and the first low-resistance portion and the like. Alternatively, some of the gate driver TFTs (preferably, those having a higher required drain breakdown voltage) provided in the gate driver circuit portion may have the dual-gate structure having the second gate electrode and the electrode and the first low-resistance portion and the like, and the others (preferably, those having a lower required drain breakdown voltage) may have a single-gate structure or a conventional dual-gate structure. Alternatively, the pixel TFTs may have the dual-gate structure having the second gate electrode, the electrode, the first low-resistance portion, and the like, whereas all of the gate driver TFTs provided in the gate driver circuit portion may have a single-gate structure or a conventional dual-gate structure.

(18) In the foregoing embodiments, the configuration has been indicated in which the array substrate is provided with the gate driver circuit portion. Alternatively, a configuration may be adopted in which the array substrate is not provided with the gate driver circuit portion. In this case, the pixel TFTs configuring the pixels in the display region have the dual-gate structure having the second gate electrode and the electrode and the first low-resistance portion and the like.

(19) In the foregoing embodiments, the configuration has been indicated in which the pixel TFT includes two gate electrodes of the first gate electrode made of the first metal film and the second gate electrode made of the second metal film. However, of the two gate electrodes, the first gate electrode made of the first metal film may be omitted.

### EXPLANATION OF SYMBOLS

15: First metal film (First electrically conductive film)
16, 116: First gate insulating film (First insulating film)
17, 117: Oxide semiconductor film (Semiconductor film)
18: Second gate insulating film (Second insulating film)
19: Second metal film (Second electrically conductive film)
20, 120: Interlayer insulating film (Third insulating film)
30, 130, 230: Gate driver TFT (Thin-film transistor)
30a, 130a, 230a: First gate electrode
30b, 130b, 230b: Source electrode
30d, 130d, 230d: Channel portion
31, 131, 231: Second gate electrode
32, 132, 232: Electrode
33, 133, 233: First low-resistance portion (Low-resistance portion)
35: Second low-resistance portion
CH4: Gate contact hole (Contact hole)

1. A thin-film transistor comprising:
a first electrically conductive film;
a semiconductor film disposed on an upper layer-side with respect to the first electrically conductive film while having a first insulating film therebetween;
a second electrically conductive film disposed on an upper layer-side with respect to the semiconductor film while having a second insulating film therebetween;
a first gate electrode formed from the first electrically conductive film;
a second gate electrode formed from the second electrically conductive film and overlapping a part of the first gate electrode;
an electrode formed from the second electrically conductive film, overlapping a part of the first gate electrode, and disposed away from the second gate electrode at an interval;
channel portions formed from the semiconductor film, one of the channel portions overlapping the second gate electrode and another one of the channel portions overlapping the electrode; and
a low-resistance portion formed from the semiconductor film, the low-resistance portion not overlapping the second gate electrode and the electrode, disposed between at least the channel portions, and having a resistance lower than that of the channel portion.

2. The thin-film transistor according to claim 1, wherein the semiconductor film includes second low-resistance portions each of which is continuous to another end of each of the channel portions of which one end thereof is continuous to the low-resistance portion, the second low-resistance portions do not overlap the second gate electrode and the electrode and have a resistance lower than that of the channel portions.

3. The thin-film transistor according to claim 1, wherein the semiconductor film is formed of an oxide semiconductor film.

4. The thin-film transistor according to claim 3, further comprising a third insulating film disposed on the upper layer-side of the second electrically conductive film and made of a material containing hydrogen.

5. The thin-film transistor according to claim 1, wherein the second gate electrode is connected to the first gate electrode via a contact hole formed in the first insulating film and the second insulating film.

6. The thin-film transistor according to claim 5, wherein the electrode is connected to the second gate electrode.

7. The thin-film transistor according to claim 1, further comprising a source electrode connected to another end of the channel portion of which one end is continuous to the low-resistance portion, wherein
the electrode is connected to the source electrode.

8. The thin-film transistor according to claim 1, further comprising a source electrode connected to another end of the channel portion of which one end is continuous to the low-resistance portion, wherein
the electrode is supplied with a signal of a voltage lower than a voltage applied to the source electrode.

9. A method of producing a thin-film transistor comprising:
a first gate electrode forming step of forming a first gate electrode by forming a first electrically conductive film and patterning the first electrically conductive film;
a first insulating film forming step of forming a first insulating film on an upper layer-side of the first electrically conductive film;
an oxide semiconductor film forming step of forming an oxide semiconductor film on an upper layer-side of the first insulating film and patterning the oxide semiconductor film;
a second insulating film forming step of forming a second insulating film on an upper layer-side of the oxide semiconductor film;
a second gate electrode and electrode forming step of forming a second electrically conductive film on an upper layer-side of the second insulating film, patterning the second electrically conductive film to form a second gate electrode overlapping a part of the first gate electrode and form an electrode overlapping a part of the first gate electrode and disposed away from the second gate electrode at an interval, and removing portions of the second insulating film that do not overlap the second gate electrode and the electrode; and
a third insulating film forming step/low-resistance portion forming step of forming a third insulating film made of a material containing hydrogen on an upper layer-side of the second electrically conductive film and according to the forming of the third insulating film, forming a low-resistance portion included in portions of the oxide semiconductor film that do not overlap the second gate electrode and the electrode and having a resistance lower than that of channel portions that are formed from the oxide semiconductor film and one of which overlaps the second gate electrode and another one of which overlaps the electrode.
